(19) United States
(12) Patent Application Publication
(10) Pub. No.: US 2026/0173622 A1
(43) Pub. Date: Jun. 18, 2026

(54) DISPLAY DEVICE WITH LIGHT EMITTING DEVICE AND MANUFACTURING METHOD THEREOF

(71) Applicant: LG Display Co., Ltd., Seoul (KR)

(72) Inventors: Jinhwa SHIN, Paju-si (KR); Jongmin JANG, Paju-si (KR); HanSaem KANG, Paju-si (KR)

(73) Assignee: LG Display Co., Ltd., Seoul (KR)

(21) Appl. No.: 19/244,963

(22) Filed: Jun. 20, 2025

(30) Foreign Application Priority Data
Dec. 18, 2024 (KR) 10-2024-0190265

(51) Int. Cl. H10H 29/853; H10H 29/01; H10H 29/80

(52) U.S. Cl. CPC H10H 29/853; H10H 29/012; H10H 29/8321

(57) ABSTRACT

A display device with a light emitting device and a manufacturing method thereof are discussed. The display device can include a substrate, and a light emitting device disposed on the substrate and located in a display area. The light emitting device can include a first electrode, an intermediate layer disposed on the first electrode, a second electrode disposed on the intermediate layer, and an encapsulation layer surrounding at least a portion of the first electrode and the intermediate layer. The second electrode can be disposed on the intermediate layer and the encapsulation layer.

### CROSS-REFERENCE TO RELATED APPLICATION

This application claims priority to Korean Patent Application No. 10-2024-0190265, filed in the Republic of Korea on Dec. 18, 2024, which is hereby incorporated by reference for all purposes as if fully set forth herein into the present application.

### BACKGROUND

### Field

Embodiments of the present disclosure relate to a display device with a light emitting device and a manufacturing method thereof.

### Discussion of the Related Art

A display device is applied to various electronic devices such as televisions, mobile phones, laptops, and tablets. Display devices can include an organic light emitting display (OLED) device that emit light on its own, and a liquid crystal display (LCD) device that require a separate light source.

Recently, display devices with light emitting diodes (LEDs) are attracting attention as next-generation display devices. Since the light emitting diodes are made of inorganic materials rather than organic materials, a display device with the light emitting diode has a characteristics of a faster lighting speed, superior light emitting efficiency, and can display high-luminance images compared to a liquid crystal display device or an organic light emitting display device.

### SUMMARY OF THE DISCLOSURE

Embodiments of the present disclosure can provide a display device having a second electrode capable of increasing the light emission efficiency of a light emitting device.

Embodiments of the present disclosure can provide a display device having an encapsulation layer that enhances the reliability of a light emitting device.

Embodiments of the present disclosure can provide a display device having an auxiliary electrode connected to a first electrode of a light emitting device through at least one hole.

Embodiments of the present disclosure can provide a manufacturing method of a light emitting device capable of easily detecting a defective light emitting device.

The objects of the embodiments of the present disclosure are not limited to the objects described in this disclosure, and other objects not mentioned will be clearly understood by those skilled in the art from the description below.

A display device according to embodiments of the present disclosure can include a substrate, and a light emitting device disposed on the substrate and located in a display area. The light emitting device can include a first electrode, an intermediate layer disposed on the first electrode, a second electrode disposed on the intermediate layer, and an encapsulation layer surrounding at least a portion of the first electrode and the intermediate layer. The second electrode can be disposed on the intermediate layer and the encapsulation layer.

A method of manufacturing a light emitting device according to embodiments of the present disclosure can include forming a crystal layer on a sapphire substrate, forming a first metal layer on the crystal layer, separating the first metal layer into a plurality of first electrodes and etching the crystal layer to a predefined first depth, forming an encapsulation layer on a side of the crystal layer and on the plurality of first electrodes, forming at least one hole in the encapsulation layer, forming a plurality of auxiliary electrodes on the encapsulation layer and connecting the plurality of auxiliary electrodes to the plurality of first electrodes to form a first intermediate product, bonding the first intermediate product to a first carrier substrate using a first adhesive layer and positioning the plurality of auxiliary electrodes on the first carrier substrate, removing the first adhesive layer and an upper portion of the encapsulation layer, forming a second metal layer on the first adhesive layer and the encapsulation layer, forming a second adhesive layer on the second metal layer and forming a second carrier substrate on the second adhesive layer, removing the first carrier substrate and the first adhesive layer to form a second intermediate product, and separating the second metal layer into a plurality of second electrodes to form a plurality of light emitting devices from the second intermediate product, wherein the second electrodes are disposed on the encapsulation layer.

According to embodiments of the present disclosure, it is possible to provide a display device having a second electrode capable of increasing the light emission efficiency of a light emitting device.

According to embodiments of the present disclosure, it is possible to provide a display device having an encapsulation layer that enhances the reliability of a light emitting device.

According to embodiments of the present disclosure, it is possible to provide a display device having an auxiliary electrode connected to a first electrode of a light emitting device through at least one hole.

According to embodiments of the present disclosure, it is possible to provide a manufacturing method of a light emitting device capable of easily detecting a defective light emitting device.

According to embodiments of the present disclosure, it is possible to provide a manufacturing method of a light emitting device capable of process optimization without separate mask process for etching a second electrode of a light emitting device.

The effects of the embodiments of the present disclosure are not limited to the effects mentioned above, and other effects not mentioned will be clearly understood by those skilled in the art from the description of the present disclosure.

### BRIEF DESCRIPTION OF THE DRAWINGS

The present disclosure will be more fully understood from the detailed description and accompanying drawings provided below, which are provided for illustration only and are not intended to limit the present disclosure.

FIG. 1 illustrates a light emitting device according to embodiments of the present disclosure.

FIGS. 2 to 14 are process cross-sectional views illustrating steps for forming the structure of FIG. 1 according to embodiments of the present disclosure.

FIG. 15 illustrates a plurality of light emitting devices transferred onto a substrate of a display panel according to embodiments of the present disclosure.

FIG. 16 is a plan view of a display device according to embodiments of the present disclosure.

FIG. 17 is a plan view of a display panel according to embodiments of the present disclosure.

FIG. 18 is a plan view of a unit driving area of a display panel according to embodiments of the present disclosure.

FIG. 19 illustrates a sub-pixel of a display panel according to embodiments of the present disclosure.

FIG. 20 is a plan view of a display panel according to embodiments of the present disclosure.

FIG. 21 is a cross-sectional view of a display panel according to embodiments of the present disclosure.

FIG. 22 is a cross-sectional view of a display panel according to embodiments of the present disclosure.

FIG. 23 is an enlarged cross-sectional view of a sub-pixel of a display panel according to embodiments of the present disclosure.

### DETAILED DESCRIPTION OF THE EMBODIMENTS

In the following description of examples or embodiments of the present invention, reference will be made to the accompanying drawings in which it is shown by way of illustration specific examples or embodiments that can be implemented, and in which the same reference numerals and signs can be used to designate the same or like components even when they are shown in different accompanying drawings from one another. Further, in the following description of examples or embodiments of the present invention, detailed descriptions of well-known functions and components incorporated herein will be omitted when it is determined that the description can make the subject matter in some embodiments of the present invention rather unclear. The terms such as “including”, “having”, “containing”, and “constituting” used herein are generally intended to allow other components to be added unless the terms are used with the term “only”. As used herein, singular forms are intended to include plural forms unless the context clearly indicates otherwise.

Terms, such as “first”, “second”, “A”, “B”, “(A)”, or “(B)” can be used herein to describe elements of the present invention. Each of these terms is not used to define essence, order, sequence, or number of elements etc., but is used merely to distinguish the corresponding element from other elements.

When it is mentioned that a first element “is connected or coupled to”, “overlaps” etc. a second element, it should be interpreted that, not only can the first element “be directly connected or coupled to” or “directly contact or overlap” the second element, but a third element can also be “interposed” between the first and second elements, or the first and second elements can “be connected or coupled to”, “overlap”, etc. each other via a fourth element. Here, the second element can be included in at least one of two or more elements that “are connected or coupled to”, “overlap”, etc. each other.

When time relative terms, such as “after,” “subsequent to,” “next,” “before,” and the like, are used to describe processes or operations of elements or configurations, or flows or steps in operating, processing and manufacturing methods, these terms can be used to describe non-consecutive or non-sequential processes or operations unless the term “directly” or “immediately” is used together.

In addition, when any dimensions, relative sizes etc. are mentioned, it should be considered that numerical values for an elements or features, or corresponding information (e.g., level, range, etc.) include a tolerance or error range that can be caused by various factors (e.g., process factors, internal or external impact, noise, etc.) even when a relevant description is not specified. Further, the term “can” fully encompasses all the meanings of the term “may” and vice versa.

Hereinafter, various embodiments of the disclosure are described in detail with reference to the accompanying drawings. All the components of each device according to all embodiments of the present disclosure are operatively coupled and configured.

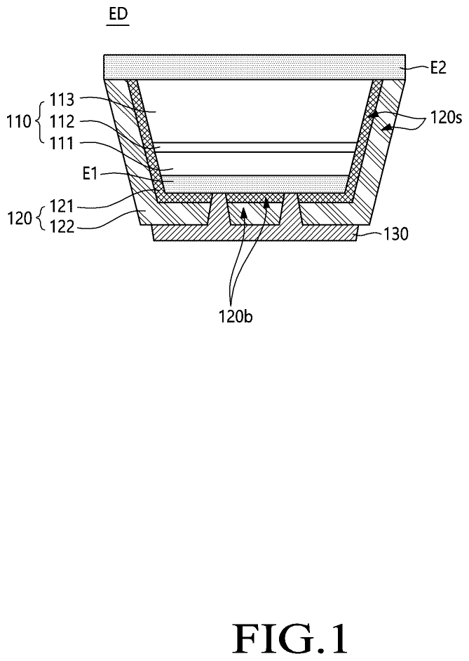

FIG. 1 illustrates a light emitting device ED according to embodiments of the present disclosure.

Referring to FIG. 1, the light emitting device ED according to embodiments of the present disclosure can include a first electrode E1, an intermediate layer 110 disposed on the first electrode E1, a second electrode E2 disposed on the intermediate layer 110, an encapsulating layer 120 surrounding at least a portion of the first electrode E1 and the intermediate layer 110, and an auxiliary electrode 130 disposed under the first electrode E1.

In the light emitting device ED according to embodiments of the present disclosure, the first electrode E1 can be an anode electrode and the second electrode E2 can be a cathode electrode. Alternatively, the first electrode E1 can be a cathode electrode and the second electrode E2 can be an anode electrode. Hereinafter, the first electrode E1 can be an anode electrode and the second electrode E2 can be a cathode electrode, but the present embodiments are not limited thereto.

Each of the first electrode E1 and the second electrode E2 can be a transparent electrode. For example, the first electrode E1 and the second electrode E2 can include a transparent conductive oxide such as indium tin oxide (ITO) or indium zinc oxide (IZO).

An intermediate layer 110 can be disposed between the first electrode E1 and the second electrode E2.

The intermediate layer 110 can include an emission layer 112, a first semiconductor layer 111 between the first electrode E1 and the emission layer 112, and a second semiconductor layer 113 between the second electrode E2 and the emission layer 112.

One of the first semiconductor layer 111 and the second semiconductor layer 113 can be implemented as a compound semiconductor of group III-V, group II-VI, and can be doped with an impurity (or dopant). For example, one of the first semiconductor layer 111 and the second semiconductor layer 113 can be a semiconductor layer doped with an n-type impurity, and the other can be a semiconductor layer doped with a p-type impurity, but the embodiments of the present disclosure are not limited thereto. For example, at least one of the first semiconductor layer 111 and the second semiconductor layer 113 can be a layer doped with an n-type or p-type impurity in a material such as gallium nitride (GaN), gallium phosphide (GaP), gallium arsenide phosphide (GaAsP), aluminum gallium indium phosphide (AlGaInP), indium aluminum phosphide (InAlP), aluminum gallium nitride (AlGaN), aluminum indium nitride (AlInN), aluminum indium gallium nitride (AlInGaN), aluminum gallium arsenide (AlGaAs), or gallium arsenide (GaAs), but the embodiments of the present disclosure are not limited thereto. For example, the n-type impurity can be silicon (Si), germanium (Ge), selenium (Se), carbon (C), tellurium (Te), or tin (Sn), but the embodiments of the present disclosure are not limited thereto. For example, the p-type impurity can be magnesium (Mg), zinc (Zn), calcium (Ca), strontium (Sr), barium (Ba), or beryllium (Be), but the embodiments of the present disclosure are not limited thereto.

For example, the first semiconductor layer 111 and the second semiconductor layer 113 can be a nitride semiconductor including an n-type impurity and a nitride semiconductor including a p-type impurity, respectively. For example, the first semiconductor layer 111 can be a nitride semiconductor containing a p-type impurity, and the second semiconductor layer 113 can be a nitride semiconductor containing an n-type impurity.

The emission layer 112 can be disposed between the first semiconductor layer 111 and the second semiconductor layer 113. The emission layer 112 can be positioned closer to the first electrode E1 than to the second electrode E2, but is not limited thereto. For example, the emission layer 112 can be positioned closer to the second electrode E2 than to the first electrode E1. As another example, a distance from the emission layer 112 to the first electrode E1 can be the same as a distance from the emission layer 112 to the second electrode E2.

The emission layer 112 can be disposed between the first semiconductor layer 111 and the second semiconductor layer 113. The emission layer 112 can receive holes and electrons from the first semiconductor layer 111 and the second semiconductor layer 113 to emit light. For example, the emission layer 112 can be configured as one of a single well structure, a multi-well structure, a single quantum well structure, a multi-quantum well (MQW) structure, a quantum dot structure, and a quantum wire structure. For example, the emission layer 112 can be configured as indium gallium nitride (InGaN) or gallium nitride (GaN). For another example, the emission layer 112 can include a multi-quantum well (MQW) structure having a well layer and a barrier layer having a higher band gap than the well layer. For example, the emission layer 112 can be formed of InGaN as a well layer and an AlGaN layer as a barrier layer.

The encapsulation layer 120 can be disposed on at least a portion of the first semiconductor layer 111, the emission layer 112, the second semiconductor layer 113, the first electrode E1, and the second electrode E2. For example, the encapsulation layer 120 can surround at least a portion of the first semiconductor layer 111, the emission layer 112, the second semiconductor layer 113, the first electrode E1, and the second electrode E2.

For example, the encapsulation layer 120 can protect the first semiconductor layer 111, the emission layer 112, and the second semiconductor layer 113. For example, the encapsulation layer 120 can cover a side of the first semiconductor layer 111, a side of the emission layer 112, and a side of the second semiconductor layer 113.

The encapsulation layer 120 can have a structure in which a reflective material is dispersed in a resin layer, but the embodiments of the present disclosure are not limited thereto. For example, the encapsulation layer 120 can be manufactured as a reflector of various structures, but the embodiments of the present disclosure are not limited thereto. Light emitted from the emission layer 112 can be reflected upward by the encapsulation layer 120, thereby improving light extraction efficiency. For example, the encapsulation layer 120 can be a reflective layer.

In the light emitting device ED according to the embodiments of the present disclosure, the encapsulation layer 120 can include a side portion 120s surrounding the side of the first electrode E1 and the intermediate layer 110, and a lower portion 120b surrounding the back surface of the first electrode E1 and having at least one hole. For example, the lower portion 120b can have a single hole. As another example, the lower portion 120b can have two or more holes.

Through at least one hole included in the lower portion 120b, the first electrode E1 can be electrically connected to an electrode and/or wiring arranged outside the light emitting device ED. If the lower portion 120b has two or more holes, the contact resistance between the first electrode E1 and the external electrode and/or wiring can be reduced compared to a case in which the lower portion 120b has a single hole.

In the light emitting device ED according to embodiments of the present disclosure, the encapsulation layer 120 can include a first encapsulation layer 121 surrounding the first electrode E1 and the intermediate layer 110, and a second encapsulation layer 122 surrounding the first encapsulation layer 121.

Since the encapsulation layer 120 is formed as a double layer structure including the first encapsulation layer 121 and the second encapsulation layer 122, the reliability of the light emitting device ED can be increased. If the encapsulation layer 120 is not strong enough and cracks occur, there can occur a short-circuit defect due to crack migration to the second electrode E2. Accordingly, a bright spot, a dark spot, a bright line, or a dark line of the light emitting device ED can be recognized.

The encapsulation layer 120 includes both the first encapsulation layer 121 surrounding the first electrode E1 and the intermediate layer 110, and the second encapsulation layer 122 surrounding the first encapsulation layer 121, thereby preventing a short-circuit defect due to crack migration to the second electrode E2, thereby increasing the reliability of the light emitting device ED.

In the light emitting device ED according to the embodiments of the present disclosure, the first encapsulation layer 121 can include a material different from the material of the second encapsulation layer 122. For example, the first encapsulation layer 121 can include aluminum oxide (Al2O3), and the second encapsulation layer 122 can include silicon nitride (SiNx) or silicon oxide (SiOx), but is not limited thereto.

In the light emitting device ED according to the embodiments of the present disclosure, a thickness of the first encapsulation layer 121 can be smaller than a thickness of the second encapsulation layer 122, or a density of the first encapsulation layer 121 can be higher than a density of the second encapsulation layer 122.

As will be described later, the process method for forming the first encapsulation layer 121 and the process method for forming the second encapsulation layer 122 can be different. Accordingly, the thickness and density of the first encapsulation layer 121 can be different from the thickness and density of the second encapsulation layer 122.

In the light emitting device ED according to the embodiments of the present disclosure, the second electrode E2 can be disposed on the intermediate layer 110 and the encapsulation layer 120. The back surface of the second electrode E2 can be in contact with the upper surface of the encapsulation layer 120. For example, the second electrode E2 can be disposed to cover the upper surface of the intermediate layer 110 and the upper surface of the encapsulation layer 120.

As will be described later, during the process of manufacturing the light emitting device ED, the second electrode E2 material can be etched while leaving a predefined size to form the second electrode E2. The light emitting device ED according to the embodiments of the present disclosure can maximize the predefined size during the process of etching the second electrode E2. Accordingly, the efficiency of the light emitting device ED can be increased and the image quality of the display panel can be improved.

In the light emitting device ED according to the embodiments of the present disclosure, an auxiliary electrode 130 can be positioned below the lower portion 120b of the encapsulation layer 120, and can be electrically connected to the first electrode E1 through at least one hole.

The auxiliary electrode 130 can be an opaque electrode. For example, the auxiliary electrode 130 can include, but is not limited to, gold (Au).

For example, the auxiliary electrode 130 can be composed of a conductive material capable of eutectic bonding. For example, the auxiliary electrode 130 of the light emitting device ED can be composed of gold (Au), tin (Sn), tungsten (W), silicon (Si), silver (Ag), titanium (Ti), iridium (Ir), chromium (Cr), indium (In), zinc (Zn), lead (Pb), nickel (Ni), platinum (Pt), and copper (Cu), or alloys thereof.

In a transfer process of the light emitting device ED, the auxiliary electrode 130 can be electrically connected to an electrode connection pattern arranged within the display panel. As will be described later, if the auxiliary electrode 130 is composed of gold (Au), the auxiliary electrode 130 and the electrode connection pattern can be bonded using eutectic bonding through heat and pressure.

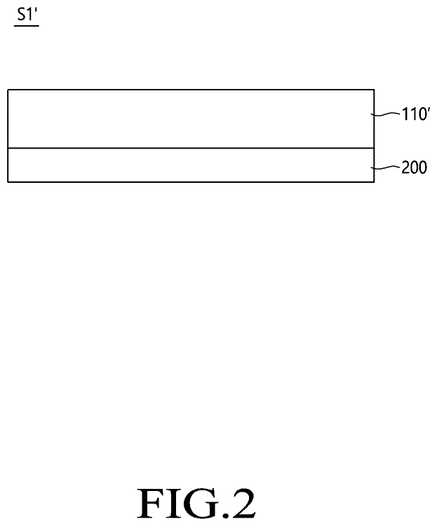

FIGS. 2 to 14 are process cross-sectional views illustrating steps for forming the structure of FIG. 1 according to embodiments of the present disclosure.

A method for manufacturing a light emitting device according to embodiments of the present disclosure can include steps 1 to 13 (S1′ to S13′).

Referring to FIG. 2, the first step S1′ can be a step of forming a crystal layer 110′ on a sapphire substrate 200.

The crystal layer 110′ can be a wafer including gallium nitride (GaN). For example, the crystal layer 110′ can be formed on the sapphire substrate 200 to a thickness of 5 to 6 μm. The crystal layer 110′ can be formed by an epitaxial growth technique. The epitaxial growth technique can be a method in which all small single crystals grown at the interface of the substrate (i.e., sapphire substrate 200) are uniformly aligned to form a single crystal layer.

The crystal layer 110′ can be epitaxially grown in sequence with an undoped semiconductor layer, an n-type impurity-doped semiconductor layer, an active layer, and a p-type impurity-doped semiconductor layer. The n-type impurity-doped semiconductor layer can include a material for forming a second semiconductor layer, the active layer can include a material for forming a emission layer, and the p-type impurity-doped semiconductor layer can include a material for forming a first semiconductor layer.

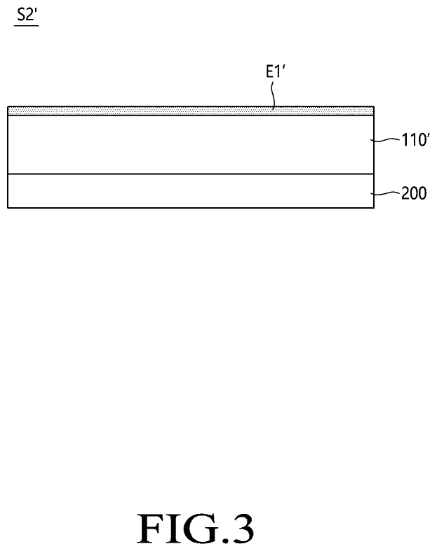

Referring to FIG. 3, the second step S2′ can be a step of forming a first metal layer E1′ on the crystal layer 110′.

The first metal layer E1′ can include indium tin oxide (ITO). The first metal layer E1′ can include a material for forming the first electrode E1. For example, the first metal layer E1′ can be formed on the crystal layer 110′ with a thickness of 120 nm.

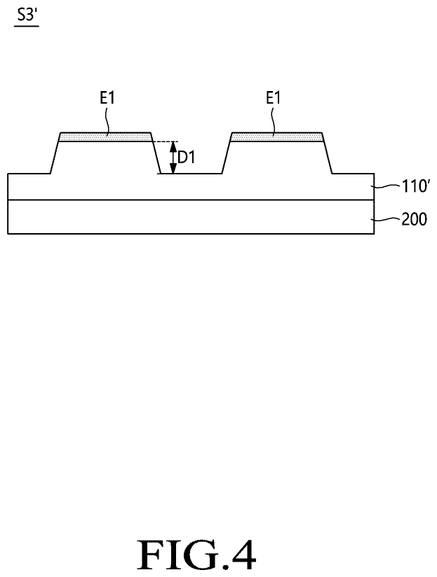

Referring to FIG. 4, the third step S3′ can be a step of separating the first metal layer E1′ into a plurality of first electrodes E1 and etching the crystal layer 110′ by a predefined first depth D1.

An area of the first metal layer E1′ excluding the plurality of first electrodes E1 can be removed. Two adjacent first electrodes E1 of the plurality of first electrodes E1 can be spaced apart by a predefined distance. The crystal layer 110′ overlapping with the area excluding the plurality of first electrodes E1 can be etched by the first depth D1. For example, the first depth D1 can be 3 μm.

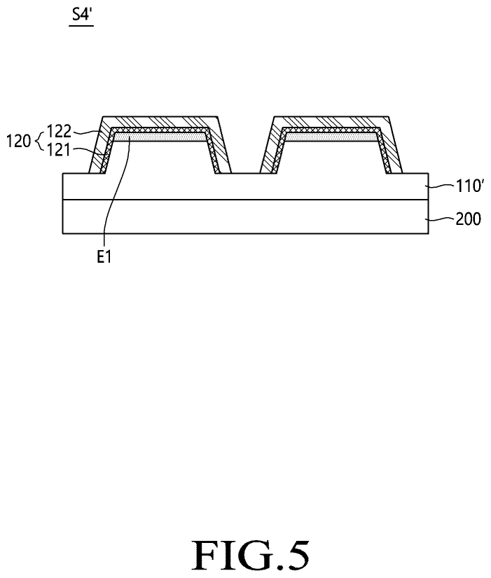

Referring to FIG. 5, the fourth step S4′ can be a step of forming a encapsulation layer 120 on the side of the crystal layer 110′ and the plurality of first electrodes E1.

A first encapsulation layer 121 can be formed to surround the side of the crystal layer 110′ and the plurality of first electrodes E1. The first encapsulation layer 121 can include aluminum oxide (Al2O3). The first encapsulation layer 121 can be formed using an atomic layer deposition (ALD) method that deposits one atomic layer per cycle. Accordingly, the first encapsulation layer 121 can include aluminum oxide having a thin thickness and high density.

A second encapsulation layer 122 can be formed to surround the first encapsulation layer 121. The second encapsulation layer 122 can include silicon nitride (SiNx) or silicon oxide (SiOx). The second encapsulation layer 122 can be formed using a sputtering method that physically deposits the particles that fall off by colliding high energy with the target material. As a result, the second encapsulation layer 122 can be thicker than the first encapsulation layer 121 and can include silicon nitride or silicon oxide with a lower density.

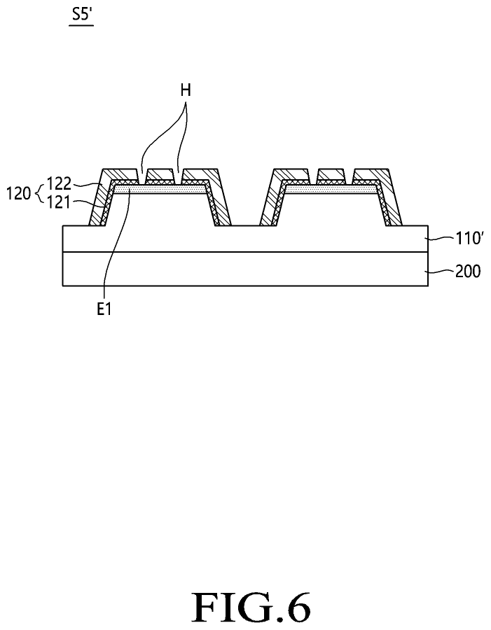

Referring to FIG. 6, the fifth step S5′ can be a step of forming at least one hole H in the encapsulation layer 120.

At least one hole H can be formed by etching the first encapsulation layer 121 and the second encapsulation layer 122. For example, at least one hole H can be formed to have a depth of 1.5 μm. By forming a plurality of holes H, a portion of the upper surface of the first electrode E1 can be exposed.

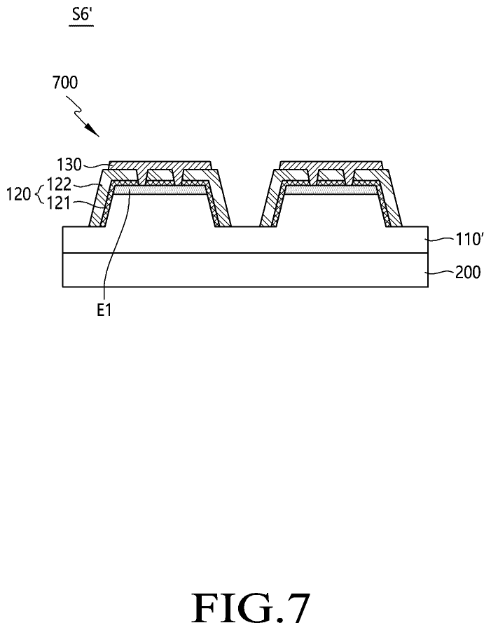

Referring to FIG. 7, the sixth step S6′ can be a step of forming a plurality of auxiliary electrodes 130 on the encapsulation layer 120 and connecting the plurality of auxiliary electrodes 130 to the plurality of first electrodes E1 to generate a first intermediate product 700.

The plurality of auxiliary electrodes 130 can be formed to fill at least one hole H formed in the encapsulation layer 120. The plurality of auxiliary electrodes 130 can be electrically connected to the first electrode E1 while coming into contact with a portion of the upper surface of the first electrode E1 exposed in the fifth step. The plurality of auxiliary electrodes 130 can include gold (Au).

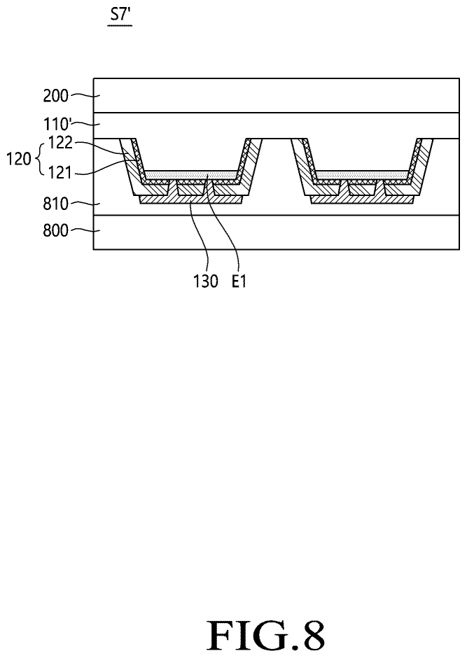

Referring to FIG. 8, the seventh step S7′ can be a step of bonding the first intermediate product 700 on a first carrier substrate 800 using a first adhesive layer 810, and positioning the plurality of auxiliary electrodes 130 on the first carrier substrate 800.

The first adhesive layer 810 including an organic adhesive material can be applied on the first intermediate product 700 of FIG. 7, thereby bonding the first intermediate product 700 and the first carrier substrate 800. Referring to FIG. 8, the first intermediate product 700 and the first carrier substrate 800 bonded to each other can be placed upside down. Accordingly, the first carrier substrate 800 can be positioned at the bottom, the plurality of auxiliary electrodes 130 can be positioned on the first carrier substrate, and the sapphire substrate 200 can be positioned at the top.

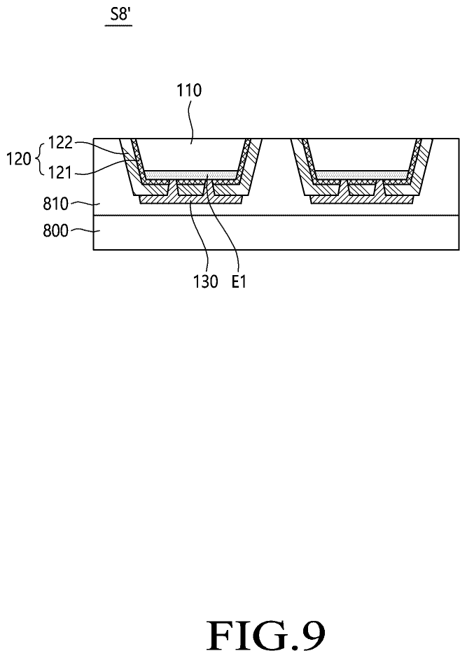

Referring to FIG. 9, an eighth step S8′ can be a step of removing or completely removing the upper portion of the first adhesive layer 810 and the encapsulation layer 120.

The sapphire substrate 200 located at the top can be detached from the crystal layer 110′ through laser lift off.

The crystal layer 110′ exposed after removing the sapphire substrate 200 can be etched until the upper surface of the first adhesive layer 810 and the encapsulation layer 120 is exposed. The etched crystal layer 110′ can be a region including an undoped semiconductor layer.

The plurality of crystal layers 110′ remaining after etching can be arranged to be spaced apart from each other, and can each include a semiconductor layer doped with an n-type impurity, an active layer, and a semiconductor layer doped with a p-type impurity. For example, each of the plurality of crystal layers 110′ can include a first semiconductor layer, a emission layer, and a second semiconductor layer, thereby forming an intermediate layer 110 of a light emitting device according to embodiments of the present disclosure.

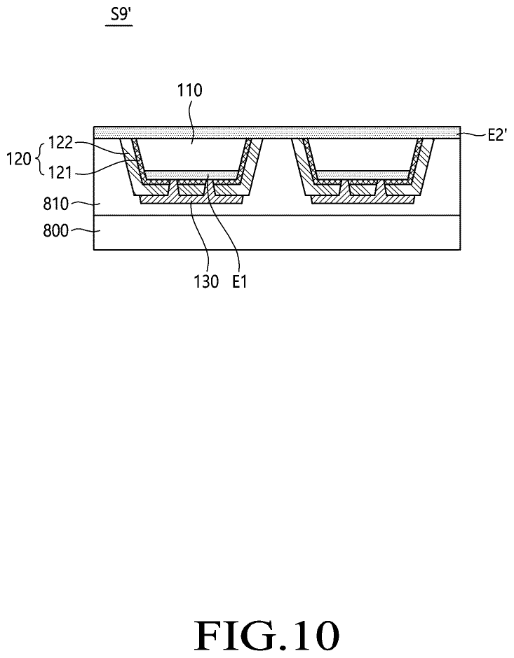

Referring to FIG. 10, a ninth step S9′ can be a step of forming a second metal layer E2′ on the first adhesive layer 810 and the encapsulation layer 120.

The second metal layer E2′ can include indium tin oxide (ITO), which is a transparent electrode material. The second metal layer E2′ can include a material for forming the second electrode E2.

The second metal layer E2′ can be formed on the entire surface. For example, the second metal layer E2′ can be formed on the upper surface of the intermediate layer 110, the upper surface of the encapsulation layer 120, and the upper surface of the first adhesive layer 810.

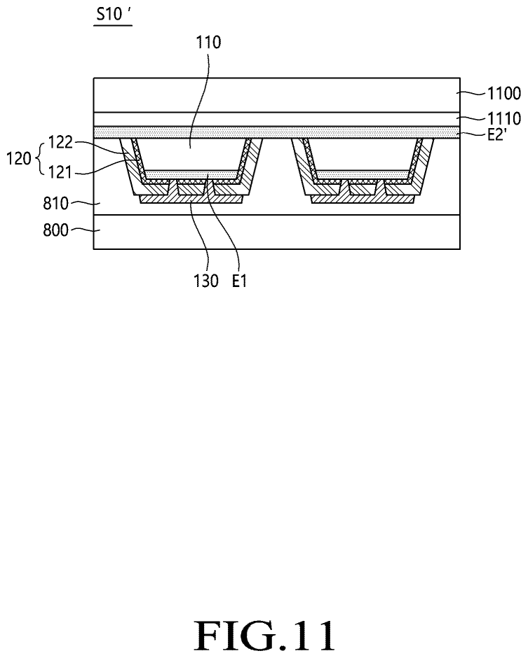

Referring to FIG. 11, a tenth step S10′ can be a step of forming a second adhesive layer 1110 on the second metal layer E2′ and forming a second carrier substrate 1100 on the second adhesive layer 1110.

The second adhesive layer 1110 can be formed on the entire surface. The second adhesive layer 1110 including an organic material that reacts to a laser can be applied on the second metal layer E2′ to bond the second metal layer E2′ and the second carrier substrate 1100.

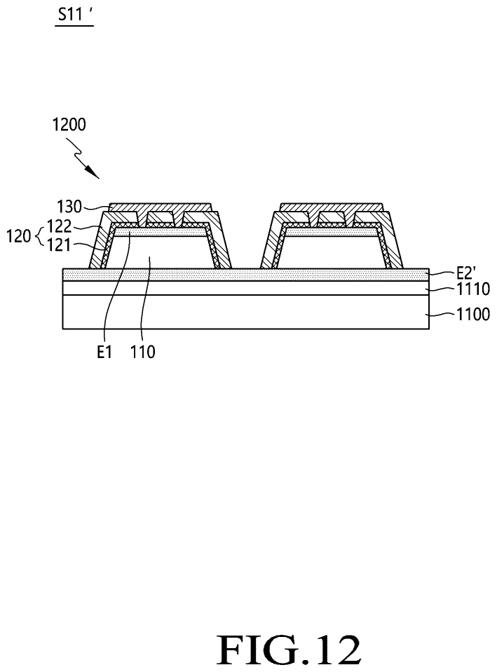

Referring to FIG. 12, an eleventh step S11′ can be a step of removing the first carrier substrate 800 and the first adhesive layer 810 to create a second intermediate product 1200.

The first carrier substrate 800 and the first adhesive layer 810 can be detached through laser lift off. The second intermediate product 1200 from which the first carrier substrate 800 and the first adhesive layer 810 are removed can be placed upside down. Accordingly, the second carrier substrate 1100 can be positioned at the bottom, the second metal layer E2′ can be positioned on the second carrier substrate, and the auxiliary electrode 130 can be positioned at the top.

The second intermediate product 1200 can be in a state in which the upper surface of the second metal layer E2′ is exposed by removing the first adhesive layer 810.

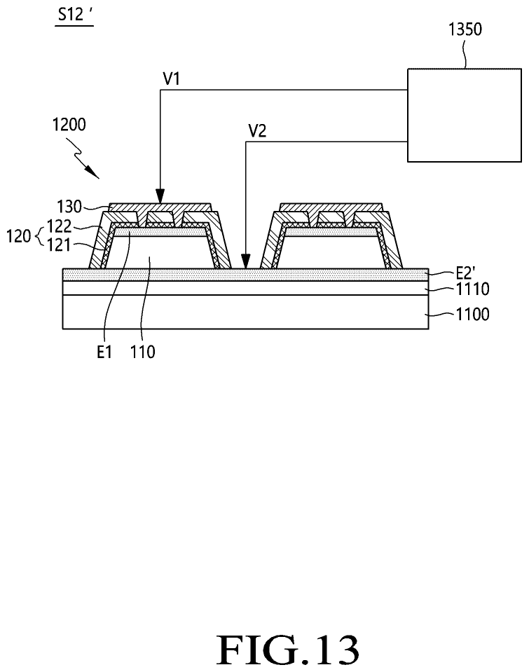

Referring to FIG. 13, a twelfth step S12′ can be a step of supplying a first voltage V1 to all or part of a plurality of auxiliary electrodes 130 using a test device 1350 in the state of the second intermediate product 1200, and supplying a second voltage V2 different from the first voltage V1 to the second metal layer E2′.

By supplying the first voltage V1 to the auxiliary electrode 130 and the second voltage V2 to the second metal layer E2′, it is possible to test the electrical/optical characteristics of the light emitting device according to the embodiments of the present disclosure.

Since the upper surface of the second metal layer E2′ is exposed, there can be easy for a probe for applying the second voltage V2 to make contact. Due to this, the electrical/optical characteristics of the light emitting devices according to the embodiments of the present disclosure can be accurately measured, and defective light emitting devices can be detected and removed. Accordingly, it is possible to improve the yield of normal light emitting devices capable of being mounted on the display panel.

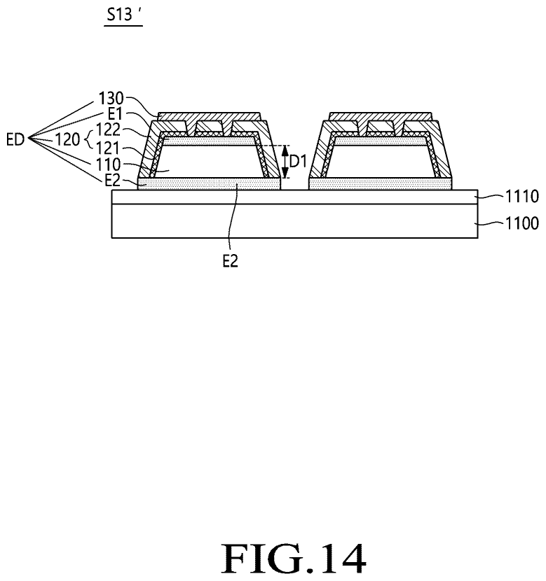

Referring to FIG. 14, a thirteenth step S13′ can be a step of forming a plurality of light emitting devices ED from the second intermediate product 1200 by separating the second metal layer E2′ into a plurality of second electrodes E2.

An area of the second metal layer E2′ excluding the plurality of second electrodes E2 can be removed through wet etching.

The second metal layer E2′ can be etched using the encapsulation layer 120 and the intermediate layer 110 as a mask. Due to this, a photolithography process for patterning the second metal layer E2′ may not be additionally performed, thereby reducing the process cost.

Since the second metal layer E2′ is not dry-etched into a plurality of second electrodes E2 through the photolithography process, it may not be restricted by the wavelength limit of light used in the photolithography process. Accordingly, the second electrode E2 may not be etched beyond a predefined etching amount. For example, the second electrode E2 can cover the upper surface of the intermediate layer 110 and the upper surface of the encapsulation layer 120 (FIG. 14 shows the state of being placed upside down), thereby maximizing the size of the second electrode. Accordingly, the emission efficiency of the light emitting device ED according to the embodiments of the present disclosure can be increased, and the image quality of the display panel can be improved.

Each of the plurality of light emitting devices ED according to the embodiments of the present disclosure can include a corresponding first electrode E1 among the plurality of first electrodes E1, a corresponding second electrode E2 among the plurality of second electrodes E2, and an intermediate layer 110 between the corresponding first electrode E1 and the corresponding second electrode E2.

The first depth D1 of the etched crystal layer 110′ in FIG. 4 can correspond to the thickness of the intermediate layer 110.

The plurality of light emitting devices ED formed from the thirteenth step S13′ can be transferred from the second carrier substrate 1100 to the substrate of the display panel through a laser transfer method. After aligning the second carrier substrate 1100 and the substrate of the display panel so as to match the areas where the plurality of light emitting devices ED are to be positioned, a laser can be irradiated in the direction in which the plurality of light emitting devices ED are disposed on the second carrier substrate 1100. Since the second adhesive layer 1110 reacts to the laser, the plurality of light emitting devices ED can be detached from the second carrier substrate 1100 and transferred onto the substrate of the display panel.

The plurality of light emitting devices ED can be transferred by a pick-and-place transfer method or a stamp transfer method instead of a laser transfer method.

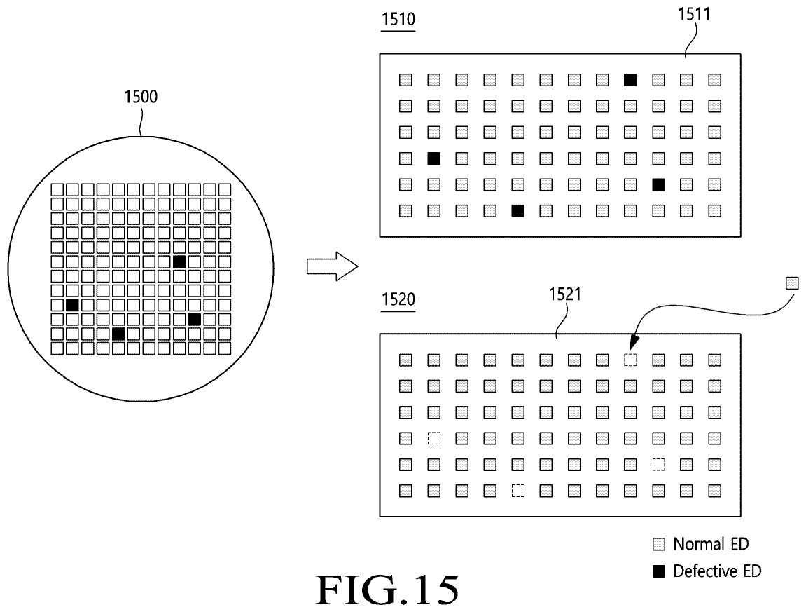

FIG. 15 illustrates a plurality of light emitting devices transferred onto a substrate of a display panel according to embodiments of the present disclosure.

Referring to FIG. 15, the plurality of light emitting devices ED formed on a carrier substrate 1500 can include normal light emitting devices ED and defective light emitting devices ED. The carrier substrate 1500 can be the second carrier substrate 1100 of FIG. 14.

The first display panel 1510 illustrates that normal light emitting devices ED and defective light emitting devices ED that are not accurately detected are transferred together onto the first substrate 1511.

In this case, it is needed a complex subsequent process of repairing the defective light emitting devices ED on the first substrate 1511 with normal light emitting devices ED. Alternatively, there can be used a redundancy structure in which a defective light emitting device ED and a light emitting device ED for replacement are arranged in duplicate.

A second display panel 1520 illustrates a case in which the electrical/optical characteristics of the light emitting devices ED are inspected to remove defective light emitting devices ED in advance, and only normal light emitting devices ED are transferred onto the second substrate 1521, according to the manufacturing method of the light emitting device ED of the embodiments of the present disclosure.

A normal light emitting device ED can be individually transferred to the empty space where the defective light emitting device ED was not transferred. This can simplify the repair process. In addition, since only the normal light emitting device ED is placed and no redundancy structure is required, the material cost can be reduced.

Hereinafter, for convenience of explanation, the second display panel 1520 and the second substrate 1521 on which only the normal light emitting device ED is disposed are referred to as “display panel” and “substrate,” respectively, and it will be described a display device including the display panel or the substrate in detail.

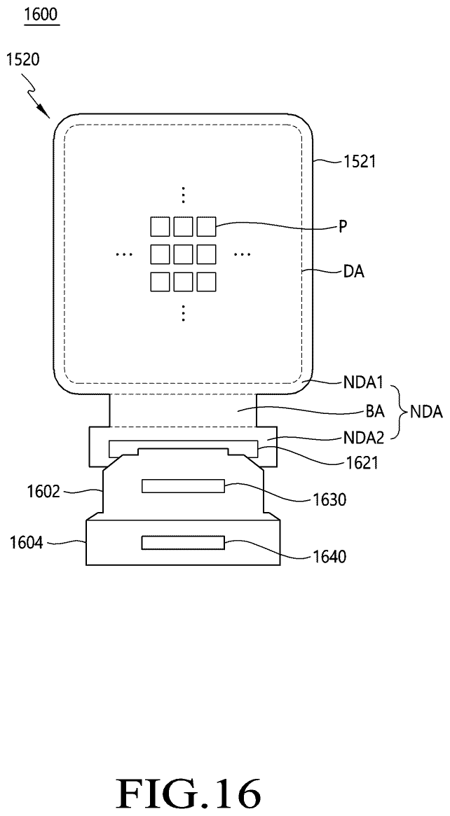

FIG. 16 is a plan view of a display device according to embodiments of the present disclosure.

Referring to FIG. 16, the display panel 1520 can include a substrate 1521. The substrate 1521 can be a member on which various components such as a plurality of metal layers and a plurality of insulating material layers are formed. The substrate 1521 can be made of an insulating material. For example, the substrate 1521 can be made of glass or resin. In addition, the substrate 1521 can be made of a flexible material. For example, the substrate 1521 can be made of a flexible plastic material such as polyimide (PI).

The display panel 1520 can display information, videos, and/or images provided to a user. For example, the display panel 1520 can include a display area DA and a non-display area NDA. For example, the substrate 1521 can include a display area DA and a non-display area NDA. The display area DA and the non-display area NDA are not limited to the substrate 1521, but can be described throughout the entire display device 1600.

The display area DA can be an area where an image is displayed. The display area DA can include a plurality of pixels P. Each of the plurality of pixels P can be composed of a plurality of sub-pixels. At least one light emitting device can be arranged in each of the plurality of sub-pixels. The light emitting device can be configured differently depending on the type of the display device 1600. For example, if the display device 1600 is an inorganic light emitting display device, the light emitting device can be an inorganic-based light emitting device, such as a light emitting diode (LED), a micro LED, or a mini LED.

The non-display area NDA can be an area where an image is not displayed. In the non-display area NDA, various wirings, and circuits for driving a plurality of pixels P of the display area DA can be arranged. For example, various driving circuits and various wirings can be arranged in the non-display area NDA, and a pad section 1621 to which an integrated circuit and a printed circuit are connected can be arranged.

For example, the driving circuit can include a data driving circuit and/or a gate driving circuit, but the embodiments of the present disclosure are not limited thereto. Wires or lines supplied with a control signal for controlling the driving circuit can be arranged on the substrate 1521. For example, the control signal can include various timing signals including a clock signal, an input data enable signal, and synchronization signals, but the embodiments of the present disclosure are not limited thereto. The control signal can be supplied to the substrate 1521 from the outside of the substrate 1521 through the pad section 1621. For example, circuit components such as a flexible printed circuit 1602 and a printed circuit board 1604 can be connected to the pad section 1621.

According to the present embodiments, the non-display area NDA can include a first non-display area NDA1, a bending area BA, and a second non-display area NDA2. For example, the first non-display area NDA1 can be an area surrounding at least a portion of the display area DA. The bending area BA can be an area extending from at least one of a plurality of sides of the first non-display area NDA1 and can be a bendable area. The second non-display area NDA2 can be an area extending from the bending area BA and can include a pad section 1621. For example, the bending area BA can be in a bent state, and the remaining area of the substrate 1521 excluding the bending area BA can be in a flat state. In this case, as the bending area BA is bent, the second non-display area NDA2 can be located on the back surface of the display area DA.

The display area DA of the substrate 1521 or the display device 1600 can be configured in various shapes according to the design of the display device 1600. For example, the display area DA can be configured in a rectangular shape with four corners formed in a round shape, a rectangular shape with four corners formed in a right angle shape, a circular shape.

The flexible printed circuit 1602 and a printed circuit board 1604 can be disposed at a lower portion of the display panel 1520. The flexible printed circuit 1602 and the printed circuit board 1604 can be arranged at one edge of the display panel 1520. One side of the flexible printed circuit 1602 can be connected to the display panel 1520, and the other side can be connected to the printed circuit board 1604. The flexible printed circuit 1602 can be a flexible film.

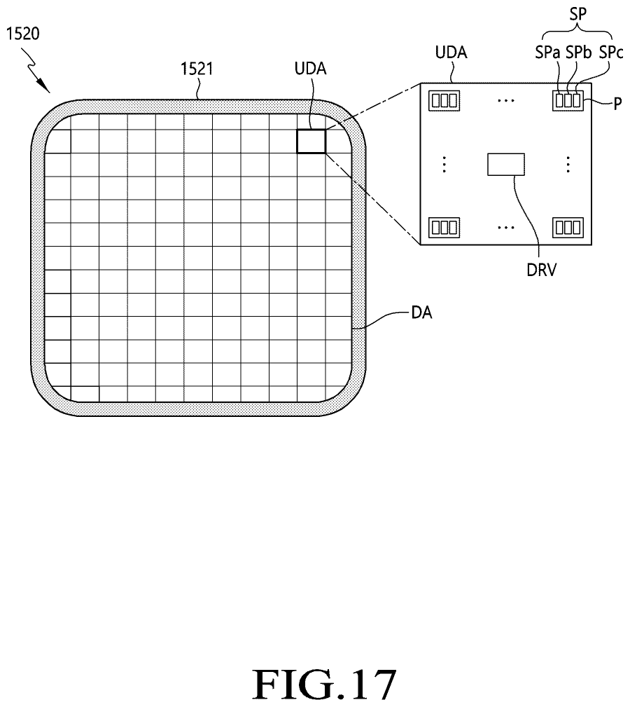

The pad section 1621 disposed in the second non-display area NDA2 includes a plurality of pads, and a driving component including one or more flexible printed circuits 1602 and a printed circuit board 1604 can be attached or bonded. The plurality of pads included in the pad section 1621 are electrically connected to one or more flexible printed circuits 1602, and can transmit various signals (or power) from the printed circuit board 1604 and one or more flexible printed circuits 1602 to a driving circuit (for example, a driver DRV of FIG. 17) arranged in the display area DA.

The flexible printed circuit 1602 can be a film in which various components are arranged on a flexible base film. For example, a first circuit component 1630, such as a gate drive integrated circuit and/or a data drive integrated circuit, can be arranged on one or more flexible printed circuits 1602. The first circuit component 1630 can be a component that processes data and a driving signal for displaying an image. The flexible printed circuit 1602 can be attached or bonded to a plurality of pads through a conductive adhesive layer.

The printed circuit board 1604 can be a component that is electrically connected to the flexible printed circuit 1602 and supplies a signal to the first circuit component 1630. Various components for supplying various signals to the first circuit component 1630 can be arranged on the printed circuit board 1604. For example, various second circuit components 1640, such as a timing controller, a power supply, a memory, or a processor, can be arranged on the printed circuit board 1604.

FIG. 17 is a plan view of a display panel 1520 according to embodiments of the present disclosure.

Referring to FIG. 17, the display area DA of the display panel 1520 according to the embodiments of the present disclosure can include a plurality of unit driving areas UDA.

The display panel 1520 according to the embodiments of the present disclosure can include a plurality of drivers DRV. The plurality of drivers DRV can be arranged in each of the plurality of unit driving areas UDA, respectively. For example, the driver DRV can be a driving chip manufactured using a MOSFET (Metal-oxide-semiconductor field effect transistor) manufacturing process on a semiconductor substrate. The display panel 1520 can include a substrate 1521 including a display area DA and a plurality of pixels P arranged in a matrix form in the display area DA.

A plurality of pixels P can be arranged in each of the plurality of unit driving areas UDA. Each of the plurality of pixels P can include a plurality of sub-pixels SP. Each of the plurality of sub-pixels SP can include at least one light emitting device.

For example, the plurality of sub-pixels SP can include a first sub-pixel SPa, a second sub-pixel SPb, and a third sub-pixel SPc, but is not limited thereto. The first sub-pixel SPa can include a first light emitting device that emits a first color light, the second sub-pixel SPb can include a second light emitting device that emits a second color light, and the third sub-pixel SPc can include a third light emitting device that emits a third color light. For example, the first color light, the second color light, and the third color light can be red light, green light, and blue light, respectively.

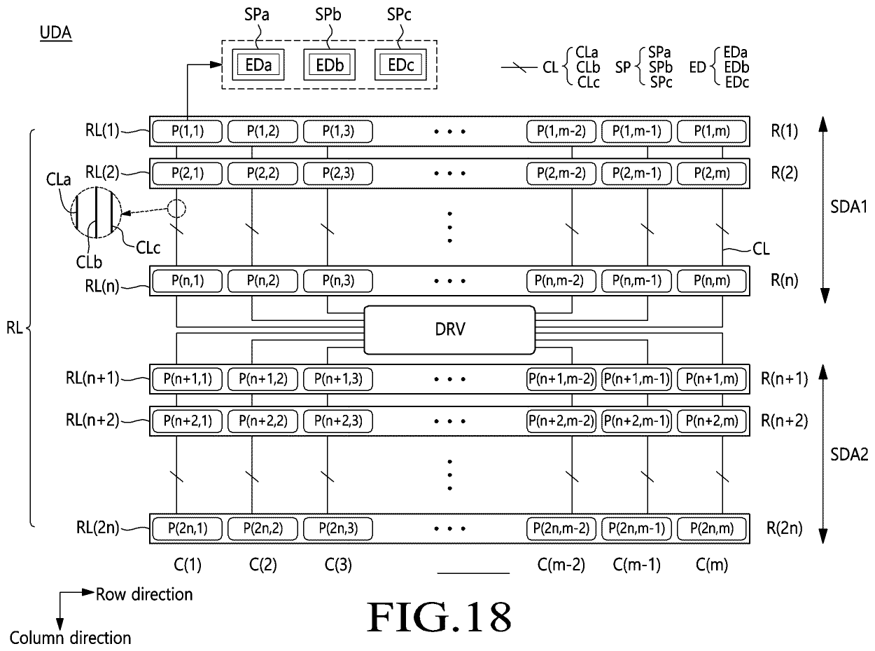

FIG. 18 is a plan view of a unit driving area of a display panel according to embodiments of the present disclosure.

Referring to FIG. 18, the display panel 1520 according to the embodiments of the present disclosure can include a plurality of row lines RL and a plurality of column lines CL. Each of the plurality of row lines RL can be arranged to extend in a row direction. The plurality of row lines RL can be electrically connected to a second electrode of each of a plurality of light emitting devices ED. Each of the plurality of column lines CL can be arranged to extend in a column direction. The plurality of column lines CL can be electrically connected to a first electrode of each of the plurality of light emitting device ED.

Each of the plurality of row lines RL can be electrically connected to the second electrode of each of the plurality of light emitting device ED. For example, the second electrodes of each of the plurality of light emitting device ED can be commonly connected to one row line RL.

Each of the plurality of column lines CL can be electrically connected to the first electrode of each of the plurality of light emitting device ED. For example, the first electrode of each of the plurality of light emitting device ED can be commonly connected to one column line CL.

For example, a line width of each of the plurality of row lines RL can be wider than a line width of each of the plurality of column lines CL.

The display panel 1520 according to the embodiments of the present disclosure can include a plurality of drivers DRV. The plurality of drivers DRV can drive the plurality of light emitting device ED, the plurality of column lines CL, and the plurality of row lines RL.

The plurality of drivers DRV can be built into the display panel 1520. The plurality of drivers DRV can be arranged in the display area DA, and can be arranged on the substrate 1521. The plurality of drivers DRV can be arranged to correspond to a plurality of unit driving areas UDA. For example, one driver DRV can be arranged in one unit driving area UDA.

Each of the plurality of drivers DRV can drive a plurality of row lines RL and a plurality of column lines CL arranged in a corresponding unit driving area UDA among the plurality of unit driving areas UDA, thereby emitting light from a plurality of light emitting device ED arranged in the corresponding unit driving area UDA.

The plurality of drivers DRV are disposed in the display area DA, and can be positioned closer to the substrate 1521 than the plurality of light emitting device ED.

For example, the plurality of row lines RL can be driven sequentially. For another example, the plurality of row lines RL can be driven simultaneously. For another example, two or more row lines RL among the plurality of row lines RL can be driven simultaneously.

For example, during a specific display driving period, among the plurality of row lines RL arranged in the unit driving area UDA, at least one row line RL can be driven, and the remaining row lines RL may not be driven.

According to the embodiments of the present disclosure, a voltage applied to the row line RL can be referred to as a low-potential voltage, and the low-potential voltage can also be referred to as a row line voltage or a cathode voltage. The low-potential voltage can have various voltage values depending on the driving type or driving state. For example, the low-potential voltage can include a first low-potential voltage, a second low-potential voltage, and a third low-potential voltage.

Driving the row line RL can mean that the first low-potential voltage is supplied to the row line RL. Not driving the row line RL can mean that the second low-potential voltage higher than the first low-potential voltage is supplied to the row line RL. Accordingly, the light emitting device ED overlapping with the driven row line RL can emit light, and the light emitting device ED overlapping with the non-driven row line RL may not emit light.

For example, any first row line RL among the plurality of row lines RL can be supplied with a first low-potential voltage during a first period, and can be supplied with a second low-potential voltage higher than the first low-potential voltage during a second period different from the first period. Accordingly, the light emitting devices ED overlapping with the first row line RL can emit light during the first period, and may not emit light during the second period different from the first period. For example, the first period and the second period can be included in one display driving period. For another example, the first period and the second period can be included in different display driving periods.

One unit driving area UDA can be divided into a first sub-driving area SDA1 and a second sub-driving area SDA2. As another example, one unit driving area UDA can be divided into three or more sub-driving areas. As another example, one unit driving area UDA may not be divided into two or more sub-driving areas.

One unit driving area UDA can include one driver DRV and (2n×m) pixels P(1, 1), . . . , P(1, m), P(2, 1), . . . , P(2, m), . . . , P(2n, 1), . . . , P(2n, m) driven by one driver DRV.

In the embodiments of the present disclosure, n can be a sequence number of a row, or the number of rows in each of the first sub-driving area SDA1 and the second sub-driving area SDA2, or the number of row lines RL in each of the first sub-driving area SDA1 and the second sub-driving area SDA2, or the number of pixel rows in each of the first sub-driving area SDA1 and the second sub-driving area SDA2. m can be a sequence number of a column, or the number of columns in each of the first sub-driving area SDA1 and the second sub-driving area SDA2, or the number of column lines CL in each of the first sub-driving area SDA1 and the second sub-driving area SDA2, or the number of pixel columns in each of the first sub-driving area SDA1 and the second sub-driving area SDA2.

In the embodiments of the present disclosure, n can be a natural number greater than or equal to 1, and m can be a natural number greater than or equal to 1.

Further, (2n×m) pixels P(1, 1), . . . , P(1, m), P(2, 1), . . . , P(2, m), . . . , P(2n, 1), . . . , P(2n, m) can be arranged in 2n rows R(1), . . . , R(2n) and m columns C(1), . . . , C(m).

Among (2n×m) pixels P(1, 1), . . . , P(1, m), P(2, 1), . . . , P(2, m), . . . , P(2n, 1), . . . , P(2n, m), (n×m) pixels P(1, 1), . . . , P(1, m), P(2, 1), . . . , P(2, m), . . . , P(n, 1), . . . , P(n, m) arranged in the first to n-th rows R(1), . . . , R(n) can be arranged in the first sub-driving area SDA1.

Among (2n×m) pixels P(1, 1), . . . , P(1, m), P(2, 1), . . . , P(2, m), . . . , P(2n, 1), . . . , P(2n, m), (n×m) pixels P(n+1, 1), . . . , P(n+1, m), P(n+2, 1), . . . , P(n+2, m), . . . , P(2n, 1), . . . , P(2n, m) arranged in the (n+1)-th to the 2n-th row R(n+1), . . . , R(2n) can be arranged in the second sub-driving area SDA2.

One unit driving area UDA can include 2n row lines RL(1), . . . , RL(2n) to drive (2n×m) pixels P(1, 1), . . . , P(1, m), P(2, 1), . . . , P(2, m), . . . , P(2n, 1), . . . , P(2n, m).

Among the 2n row lines RL(1), . . . , RL(2n), the first to n-th row lines RL(1), . . . , RL(n) can be arranged in the first sub-driving area SDA1. Among the 2n row lines RL(1), . . . , RL(2n), the (n+1)-th to the 2n-th row lines R(n+1), . . . , R(2n) can be arranged in the second sub-driving area SDA2.

Each of the 2n row lines RL(1), . . . , RL(2n) can overlap with m pixels. For example, the first row line RL(1) can overlap with m pixels P(1, 1), . . . , P(1, m) arranged in the first row R(1). The n-th row line RL(n) can overlap with m pixels P(n, 1), . . . , P(n, m) arranged in the n-th row R(n). The (n+1)-th row line RL(n+1) can overlap with the m pixels P(n+1, 1), . . . , P(n+1, m) arranged in the (n+1)-th row R(n+1). The 2n-th row line RL(2n) can overlap with the m pixels P(2n, 1), . . . , P(2n, m) arranged in the 2nth row R(2n).

For example, the first row line RL(1) can be connected to the k sub-pixels SPa, SPb and SPc included in each of the m pixels P(1, 1), . . . , P(1, m) arranged in the first row R(1). More specifically, the first row line RL(1) can be connected to the second electrodes of the k light emitting devices EDa, EDb and EDc included in each of the m pixels P(1, 1), . . . P(1, m) arranged in the first row R(1).

For example, the n-th row line RL(n) can be connected to the k sub-pixels SPa, SPb and SPc included in each of the m pixels P(n, 1), . . . , P(n, m) arranged in the n-th row R(n). More specifically, the n-th row line RL(n) can be connected to the first electrodes of the k light emitting devices EDa, EDb and EDc included in each of the m pixels P(n, 1), . . . , P(n, m) arranged in the n-th row R(n).

For example, the (n+1)-th row line RL(n+1) can be connected to k sub-pixels SPa, SPb and SPc included in each of m pixels P(n+1, 1), . . . , P(n+1, m) arranged in the (n+1)-th row R(n+1). More specifically, the (n+1)-th row line RL(n+1) can be connected to first electrodes of k light emitting devices EDa, EDb and EDc included in each of m pixels P(n+1, 1), . . . P(n+1, m) arranged in the (n+1)-th row R(n+1).

For example, the 2n-th row line RL(2n) can be connected to k sub-pixels SPa, SPb and SPc included in each of m pixels P(2n, 1), . . . , P(2n, m) arranged in the 2n-th row R(2n). More specifically, the 2n-th row line RL(2n) can be connected to first electrodes of k light emitting devices EDa, EDb and EDc included in each of m pixels P(2n, 1), . . . P(2n, m) arranged in the 2n-th row R(2n).

One unit driving area UDA can include (m×k×2) column lines CL to drive (2n×m) pixels P(1, 1), . . . , P(1, m), P(2, 1), . . . , P(2, m), . . . , P(2n, 1), . . . , P(2n, m). Here, k is the number of sub-pixels SP included in one pixel P. In the example of FIG. 18, k is 3. For example, one pixel P can include three sub-pixels SPa, SPb and SPc.

The first sub-driving area SDA1 can include (m×k) column lines CL to drive (n×m) pixels P(1, 1), . . . , P(1, m), . . . , P(n, 1), . . . , P(n, m) arranged in the first sub-driving area SDA1. In the example of FIG. 18, since k is 3, the first sub-driving area SDA1 can include 3m column lines CL.

In the first sub-driving area SDA1, k column lines CLa, CLb and CLb can be arranged in each of the m columns C(1), . . . , C(m). In the example of FIG. 18, since k is 3, in the first sub-driving area SDA1, each of the m columns C(1), . . . , C(m) can include three column lines CLa, CLb and CLc.

In each of the m columns C(1), . . . , C(m), each of the k column lines CL can be commonly connected to n pixels arranged in the corresponding column. In each of the m columns C(1), . . . , C(m), each of the k column lines CL can be commonly connected to first electrodes of n light emitting devices ED arranged in the corresponding column. In the example of FIG. 18, since k is 3, in each of the m columns C(1), . . . , C(m), three column lines CLa, CLb and CLc can be connected to the first electrodes of the 3n light emitting devices ED included in the n pixels arranged in the corresponding column. For example, in each of the m columns C(1), . . . , C(m), a first column line CLa can be commonly connected to the first electrodes of the n first light emitting devices EDa arranged in the corresponding column. In each of the m columns C(1), . . . , C(m), a second column line CLb can be commonly connected to the first electrodes of the n second light emitting devices EDb arranged in the corresponding column. In each of the m columns C(1), . . . , C(m), a third column line CLc can be commonly connected to the first electrodes of the n third light emitting devices EDc arranged in the corresponding column.

The second sub-driving area SDA2 can include (m×k) column lines CL to drive (n×m) pixels P(n+1, 1), . . . , P(n+1, m), . . . , P(2n, 1), . . . , P(2n, m) arranged in the second sub-driving area SDA2. In the example of FIG. 18, since k is 3, the second sub-driving area SDA2 can include 3m column lines CL.

In the second sub-driving area SDA2, k column lines CL can be arranged in each of the m columns C(1), . . . , C(m). In the example of FIG. 18, since k is 3, in the second sub-driving area SDA2, each of the m columns C(1), . . . , C(m) can include three column lines CLa, CLb and CLc.

In each of the m columns C(1), . . . , C(m), each of the k column lines CL can be commonly connected to n pixels arranged in the corresponding column. In each of the m columns C(1), . . . , C(m), each of the k column lines CL can be commonly connected to first electrodes of n light emitting devices ED arranged in the corresponding column. In the example of FIG. 18, since k is 3, in each of the m columns C(1), . . . , C(m), three column lines CLa, CLb and CLc can be connected to the first electrodes of the 3n light emitting devices ED included in the n pixels arranged in the corresponding column. For example, in each of the m columns C(1), . . . , C(m), a first column line CLa can be commonly connected to the first electrodes of the n first light emitting devices EDa arranged in the corresponding column. In each of the m columns C(1), . . . , C(m), the second column line CLb can be commonly connected to the first electrodes of the n second light emitting devices EDb arranged in the corresponding column. In each of the m columns C(1), . . . , C(m), the third column line CLc can be commonly connected to the first electrodes of the n third light emitting devices EDc arranged in the corresponding column.

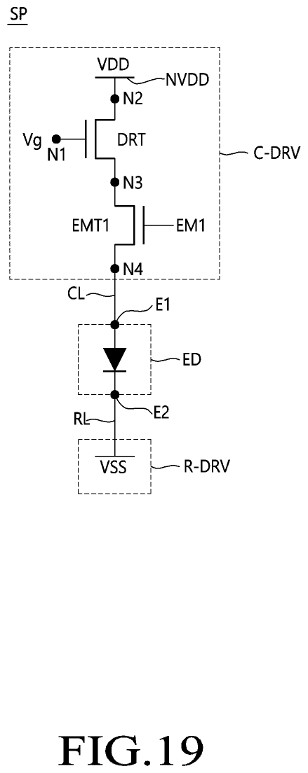

FIG. 19 illustrates a sub-pixel SP of a display panel according to embodiments of the present disclosure.

Referring to FIG. 19, the sub-pixel SP according to embodiments of the present disclosure can include a light emitting device ED including a first electrode E1 and a second electrode E2, a column driver C-DRV for driving a column line CL electrically connected to the first electrode E1 of the light emitting device ED, and a row driver R-DRV for driving a row line RL electrically connected to the second electrode E2 of the light emitting device ED.

The light emitting device ED can include a first electrode E1 and a second electrode E2. The first electrode E1 can be electrically connected to a column line CL, and the second electrode E2 can be electrically connected to a row line RL. For example, the first electrode E1 can be an anode electrode, and the second electrode E2 can be a cathode electrode. For another example, the first electrode E1 can be a cathode electrode, and the second electrode E2 can be an anode electrode.

The column driver C-DRV included in a unit driving area UDA can be connected to a plurality of column lines CL included in the unit driving area UDA, and can drive a plurality of column lines CL included in the unit driving area UDA. Each of the plurality of column lines CL can be commonly connected to the first electrode E1 of each of the plurality of light emitting devices ED included in the plurality of sub-pixels SP arranged in the corresponding column.

The row driver R-DRV included in a unit driving area UDA can be connected to a plurality of row lines RL included in the unit driving area UDA and can drive a plurality of row lines RL included in the unit driving area UDA. Each of the plurality of row lines RL can be commonly connected to a second electrode E2 of each of a plurality of light emitting devices ED included in a plurality of sub-pixels SP arranged in the corresponding row.

The column driver C-DRV can include main nodes including a first node N1, a second node N2, a third node N3, and a fourth node N4. The column driver C-DRV can include a driving transistor DRT and a first emission control transistor EMT1.

The first node N1 can be a node to which a voltage Vg for controlling the on-off of the driving transistor DRT is applied. The second node N2 can be a node electrically connected to a high-potential voltage node NVDD to which a high-potential voltage VDD is applied. The third node N3 can be a node to which the driving transistor DRT and the first emission control transistor EMT1 are connected. The fourth node N4 can be a node to which the first emission control transistor EMT1 and the light emitting device ED are electrically connected, and can be a node to which the column line CL is electrically connected. Here, a source electrode or a drain electrode of the first emission control transistor EMT1 and the first electrode E1 of the light emitting device ED can be commonly connected to the column line CL.

The driving transistor DRT supplies a driving current to make the light emitting device ED emit light, is connected between the second node N2 and the third node N3, and can control the connection between the second node N2 and the third node N3 according to the voltage of the first node N1.

The gate electrode of the driving transistor DRT is electrically connected to the first node N1, and a gate voltage Vg can be applied thereto. The drain electrode or the source electrode of the driving transistor DRT can be electrically connected to the second node N2. The source electrode or the drain electrode of the driving transistor DRT can be electrically connected to the third node N3.

The first emission control transistor EMT1 can control a connection of a path through which the driving current flows, and can play a role in controlling an emission of the light emitting device ED.

If the driving transistor DRT and the first emission control transistor EMT1 are turned on between a high potential voltage VDD and a low potential voltage VSS, the driving current can be supplied to the light emitting device ED through the driving transistor DRT and the first emission control transistor EMT1. Accordingly, the light emitting device ED can emit light.

The first emission control transistor EMT1 is connected between the third node N3 and the fourth node N4, and can control the connection between the third node N3 and the fourth node N4 according to a first emission control signal EM1. The first emission control signal EM1 can be applied to the gate electrode of the first emission control transistor EMT1. The drain electrode or the source electrode of the first emission control transistor EMT1 can be electrically connected to the third node N3. The source electrode or drain electrode of the first emission control transistor EMT1 can be electrically connected to the fourth node N4.

The first emission control signal EM1 can be a pulse width modulation signal that varies at a predefined time (for example, each frame, or each sub-frame included in one frame), but the embodiments of the present disclosure are not limited thereto.

The row driver R-DRV can drive at least one row line RL by supplying a low-potential voltage VSS to at least one row line RL.

The row driver R-DRV can perform display-on driving or display-off driving for one row line RL. The row driver R-DRV can supply a low-potential voltage for display-on driving to one row line RL in order to perform display-on driving for one row line RL. The row driver R-DRV can supply a low-potential voltage for display-off driving to one row line RL in order to perform display-off driving for one row line RL.

A low-potential voltage for display-on driving and a low-potential voltage for display-off driving can be different. For example, the low-potential voltage for display-on driving can be lower than the low-potential voltage for display-off driving. In the embodiments of the present disclosure, the “low-potential voltage for display-on driving” is also referred to as the “first low-potential voltage,” and the “low-potential voltage for display-off driving” is also referred to as the “second low-potential voltage.”

The column driver C-DRV can further include at least one switching element and/or at least one transistor in addition to the driving transistor DRT and the first emission control transistor EMT1. Each of the transistors included in the column driver C-DRV can be an n-type transistor or a p-type transistor.

The column driver C-DRV can further include at least one capacitor. The column driver C-DRV can further include at least one circuit element. For example, the at least one circuit element can include a power output buffer.

The row driver R-DRV can include at least one switching element and/or at least one transistor. Each of the transistors included in the row driver R-DRV can be an n-type transistor or a p-type transistor. The row driver R-DRV can further include at least one circuit element. For example, at least one circuit element can include a power output buffer.

The column driver C-DRV and the row driver R-DRV can be internal circuits included in the driver DRV. As another example, the column driver C-DRV and the row driver R-DRV may not be included in the driver DRV and can be circuits formed on the substrate 1521 of the display panel 1520.

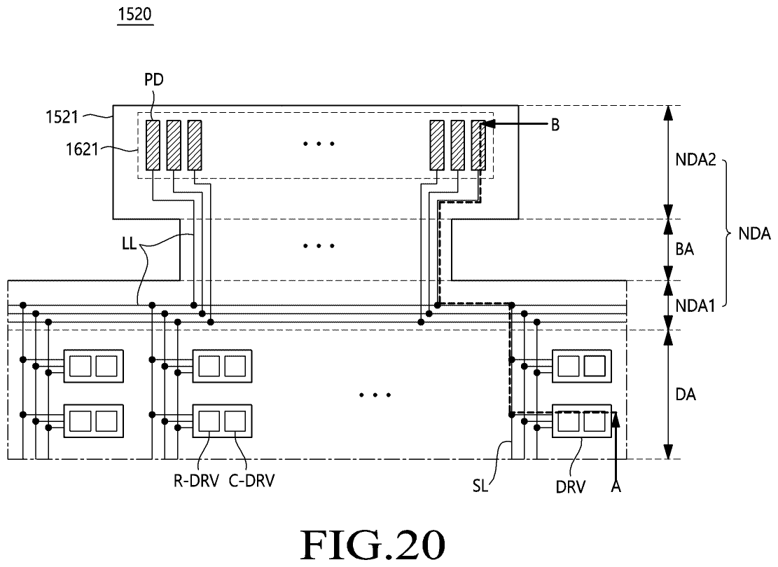

FIG. 20 is a plan view of the display panel according to the embodiments of the present disclosure.

Referring to FIG. 20, the substrate 1521 of the display panel 1520 according to the embodiments of the present disclosure can include a display area DA and a non-display area NDA, and the non-display area NDA can include a first non-display area NDA1, a bending area BA, and a second non-display area NDA2.

A plurality of drivers DRV can be arranged in the display area DA. The plurality of drivers DRV can be disposed between the substrate 1521 and the light emitting device ED, and electrically connected to the first electrode and the second electrode of the light emitting device ED. Each of the plurality of drivers DRV can be a circuit for driving light emitting devices of a plurality of sub-pixels included in a corresponding unit driving area (UDA of FIGS. 17 and 18). Each of the plurality of drivers DRV can include a row driver R-DRV for driving a plurality of row lines and a column driver C-DRV for driving a plurality of column lines, in order to drive a plurality of light emitting devices ED included in a corresponding unit driving area (UDA of FIGS. 17 and 18).

A pad section 1621 including a plurality of pads PD can be arranged in the second non-display area NDA2.

A plurality of signal lines SL and a plurality of link lines LL for signal transmission between a plurality of drivers DRV arranged in the display area DA and the pad section 1621 can be arranged on the substrate 1521. The plurality of signal lines SL can be electrically connected between the plurality of link lines LL and the plurality of drivers DRV. The plurality of link lines LL can electrically connect the plurality of pads PD and the plurality of signal lines SL.

The plurality of link lines LL can be arranged in the non-display area NDA, and all or part of each of the plurality of signal lines SL can be arranged in the display area DA.

Each of the plurality of drivers DRV can receive various signals to perform a driving operation through the plurality of link lines LL and the plurality of signal lines SL. Here, the various signals can include various power voltages and various signals required for the driving operation of each of the plurality of drivers DRV.

As the bending area BA is bent, a portion of the plurality of link lines LL can also be bent. Stress can be concentrated on a portion of the bent link line LL, and thus cracks can occur in the link line LL. Accordingly, the plurality of link lines LL can be formed of a conductive material having excellent ductility to reduce cracks when the bending area BA is bent. For example, the plurality of link lines LL can be formed of a conductive material having excellent ductility. In addition, the plurality of link lines LL can be composed of one of various conductive materials used in the display area DA. The plurality of link lines LL can be composed of a multilayer structure including various conductive materials. The plurality of link lines LL can be composed of various shapes to reduce stress. At least a portion of the plurality of link lines LL arranged on the bending area BA can extend in the same direction as the extension direction of the bending area BA, or can extend in a direction different from the extension direction of the bending area BA to reduce stress.

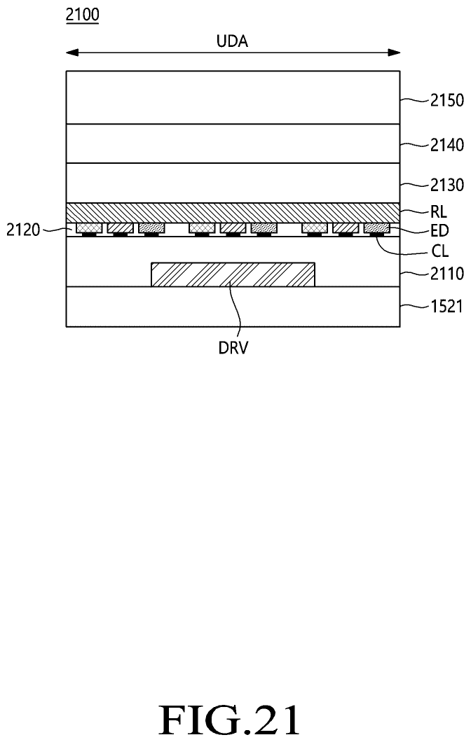

FIG. 21 is a cross-sectional view of a display panel according to embodiments of the present disclosure. Specifically, FIG. 21 is a cross-sectional view of a portion of a unit driving area UDA in which one driver DRV is disposed.

Referring to FIG. 21, the display panel 2100 can include a substrate 1521, a driver DRV on the substrate 1521, a layer stack 2110 on the driver DRV, a plurality of light emitting devices ED disposed on the layer stack 2110, an optical layer 2120 disposed on the layer stack 2110 and between the plurality of light emitting devices ED, an overcoat layer 2130 disposed on the plurality of light emitting devices ED and the optical layer 2120, an adhesive layer 2140 disposed on the overcoat layer 2130, and a cover member 2150 arranged on the adhesive layer 2140.

A plurality of column lines CL can be arranged on the layer stack 2110. Each of the plurality of column lines CL can be arranged between the layer stack 2110 and the light emitting device ED. The plurality of row lines RL can be arranged on the plurality of light emitting devices ED and the optical layer 2120.

The display panel 2100 can include a substrate 1521 including a display area DA, a plurality of light emitting devices ED disposed in the display area DA, a plurality of column lines CL electrically connected to a first electrode E1 of each of the plurality of light emitting devices ED, a plurality of row lines RL electrically connected to a second electrode E2 of each of the plurality of light emitting devices ED, and a plurality of drivers DRV configured to drive the plurality of light emitting devices ED, the plurality of column lines CL, and the plurality of row lines RL.

The plurality of drivers DRV can be disposed in the display area DA, and can be disposed between the substrate 1521 and the plurality of light emitting devices ED, but can be positioned closer to the substrate 1521 than the plurality of light emitting devices ED.

The layer stack 2110 can include a plurality of insulating layers. The plurality of insulating layers can include a plurality of organic layers. At least one of the plurality of organic layers can be disposed on a side of the driver DRV. For example, two or more organic layers can be disposed on a side of the driver DRV.

The layer stack 2110 can further include at least one metal layer connecting the driver DRV and the column line CL, and at least one metal layer connecting the driver DRV and the row line RL.

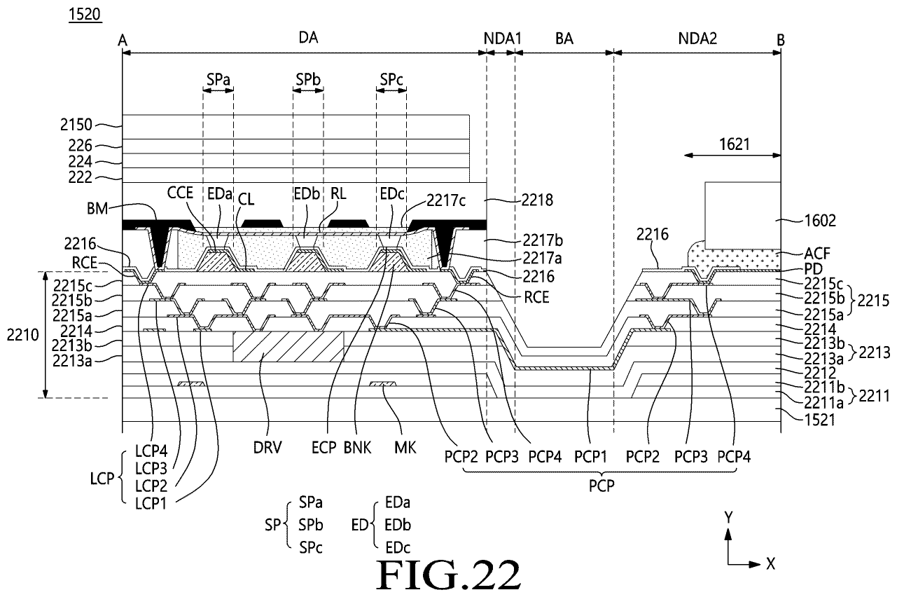

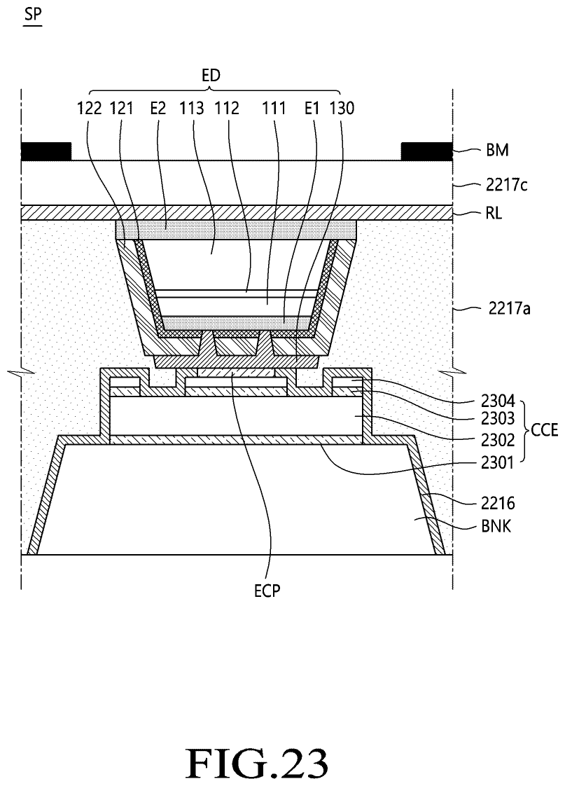

FIG. 22 is a detailed cross-sectional view of a display panel 1520 according to embodiments of the present disclosure taken along the A-B cutting line of FIG. 20, and FIG. 23 is an enlarged cross-sectional view of a sub-pixel SP of a display panel 1520 according to embodiments of the present disclosure. However, FIG. 22 is a cross-sectional view of a display area DA, a first non-display area NDA, a bending area BA, and a second non-display area NDA.

Meanwhile, for convenience of illustration, the A-B cutting line in FIG. 20 is illustrated as not overlapping with a signal line SL and a link line LL, but the A-B cutting line in FIG. 20 is intended to indicate the same position as the adjacent signal line SL and the link line LL.

Referring to FIG. 22, a buffer layer 2211 can be included on the substrate 1521. The buffer layer 2211 can include a first buffer layer 2211a and a second buffer layer 2211b. The first buffer layer 2211a and the second buffer layer 2211b can be arranged in the display area DA, the first non-display area NDA1, and the second non-display area NDA, and may not be arranged in the entirety or part of the bending area BA.

The first buffer layer 2211a and the second buffer layer 2211b can reduce the penetration of moisture or impurities through the substrate 1521. The first buffer layer 2211a and the second buffer layer 2211b can be made of an inorganic insulating material. For example, the first buffer layer 2211a and the second buffer layer 2211b can be composed of a single layer or multiple layers of silicon oxide (SiOx) or silicon nitride (SiNx).

For example, a portion of the first buffer layer 2211a and the second buffer layer 2211b on the bending area BA can be removed. The upper surface of the substrate 1521 located on the bending area BA can be exposed by the area (e.g., opening) where the first buffer layer 2211a and the second buffer layer 2211b are removed.

By removing the first buffer layer 2211a and the second buffer layer 2211b from the bending area BA, it is possible to minimize an occurrence of cracks in the first buffer layer 2211a and the second buffer layer 2211b that can occur during bending.

A plurality of alignment keys MK can be arranged between the first buffer layer 2211a and the second buffer layer 2211b. The plurality of alignment keys MK can be configured to identify the position of the driver DRV during the manufacturing process of the display panel 1520. For example, the plurality of alignment keys MK can be configured to align the position of the driver DRV transferred on the adhesive layer 2212. In another example, the plurality of alignment keys MK can be omitted.

An adhesive layer 2212 can be disposed on the second buffer layer 2211b. The adhesive layer 2212 can be disposed in the display area DA, the first non-display area NDA1, the bending area BA, and the second non-display area NDA2. For another example, at least a portion of the adhesive layer 2212 can be removed in the non-display area NDA including the bending area BA. For example, the adhesive layer 2212 can be made of any one of an adhesive polymer, an epoxy resin, a UV-curable resin, a polyimide series, an acrylate series, a urethane series, and a polydimethylsiloxane (PDMS).

A driver DRV can be disposed on the adhesive layer 2212 in the display area DA. If the driver DRV is implemented as a driving chip (e.g., driver integrated circuit), the driving driver can be mounted on the adhesive layer 2212 by a transfer process.

The display panel 1520 can further include a side protection layer 2213 disposed on the side of the plurality of drivers DRV, and an upper protection layer 2214 disposed on the plurality of drivers DRV and the side protection layer 2213. For example, the side protection layer 2213 can include at least one of a first protection layer 2213a and a second protection layer 2213b disposed on the side of the plurality of drivers DRV, and in some cases, can further include at least one additional protection layer. The first protection layer 2213a and the second protection layer 2213b can be disposed on the adhesive layer 2212. The first protection layer 2213a and the second protection layer 2213b can be arranged to surround the side surface of the driver DRV. For example, the second protection layer 2213b can be arranged to cover at least a portion of the upper surface of the driver DRV.

At least one of the first protection layer 2213a and the second protection layer 2213b arranged on the bending area BA can be omitted. For example, the first protection layer 2213a can be arranged entirely on the display area DA and the non-display area NDA, and the second protection layer 2213b can be partially arranged on the display area DA, the first non-display area NDA1, and the second non-display area NDA2.

For example, the side protection layer 2213 including at least one of the first protection layer 2213a and the second protection layer 2213b can be composed of an organic insulating material (i.e., organic layer), but the embodiments of the present disclosure are not limited thereto. For example, the first protection layer 2213a and the second protection layer 2213b can be composed of a photo resist, a polyimide (PI), or a photo acryl-based material. For example, the first protection layer 2213a and the second protection layer 2213b can be an overcoating layer or an insulating layer.

The display panel 1520 can further include a plurality of insulating layers 2215 disposed on the upper protective layer 2214. For example, the plurality of insulating layers 2215 can include a first insulating layer 2215a, a second insulating layer 2215b, and a third insulating layer 2215c.

In the display area DA, a plurality of line connection patterns LCP can be arranged on the second protection layer 2213b. The plurality of line connection patterns LCP can be wiring for electrically connecting the driver DRV to other components. For example, the driver DRV can be electrically connected to a plurality of column lines CL, a plurality of row lines RL, and a plurality of row connection electrodes RCE through the plurality of line connection patterns LCP.

For example, the plurality of line connection patterns LCP can include a first line connection pattern LCP1, a second line connection pattern LCP2, a third line connection pattern LCP3, and a fourth line connection pattern LCP4. For example, the first line connection pattern LCP1, the second line connection pattern LCP2, the third line connection pattern LCP3, and the fourth line connection pattern LCP4 can be arranged in different metal layers.

For example, a plurality of first line connection patterns LCP1 can be arranged on the second protection layer 2213b. The plurality of first line connection patterns LCP1 can be electrically connected to the driver DRV. The plurality of first line connection patterns LCP1 can transmit the voltage output from the driver DRV to the column line CL or the row line RL.

The display panel 1520 can further include a side protection layer 2213 including at least one of the first protection layer 2213a and the second protection layer 2213b, and an upper protection layer 2214 arranged on the plurality of drivers DRV. For example, the upper protection layer 2214 can include a third protection layer 2214, and in some cases, can further include at least one additional protection layer. The third protection layer 2214 can be disposed on the second protection layer 2213b and the plurality of first line connection patterns LCP1. The third protection layer 2214 can be disposed entirely in the display area DA and the non-display area NDA. In the bending area BA, the third protection layer 2214 can cover or enclose the side surface of the second protection layer 2213b and the upper surface of the first protection layer 2213a.

For example, the third protection layer 2214 can be composed of an organic insulating material. For example, the third protection layer 2214 can be composed of a photo resist, a polyimide (PI), or a photo acryl-based material. For example, the first protection layer 2213a, the second protection layer 2213b, and the third protection layer 2214 can be composed of the same insulating material, or at least one of the first protection layer 2213a, the second protection layer 2213b, and the third protection layer 2214 can be composed of a different insulating material from the rest.

A plurality of second line connection patterns LCP2 can be arranged on the third protection layer 2214. The plurality of second line connection patterns LCP2 can be electrically connected or directly connected to the driver DRV. For example, some of the second line connection patterns LCP2 can be directly or indirectly connected to the driver DRV through contact holes of the third protection layer 2214. Other parts of the second line connection patterns LCP2 can be electrically connected to the first line connection pattern LCP1 through contact holes of the third protection layer 2214. The voltage output from the driver DRV can be transmitted to the column line CL or the row line RL through the plurality of second line connection patterns LCP2 and other connection patterns.

A first insulating layer 2215a can be disposed on the plurality of second line connection patterns LCP2. The first insulating layer 2215a can be disposed entirely over the display area DA and the non-display area NDA. The first insulating layer 2215a can be composed of an organic insulating material. For example, the first insulating layer 2215a can be composed of a photo resist, a polyimide (PI), or a photo acryl-based material.

A plurality of third line connection patterns LCP3 can be disposed on the first insulating layer 2215a. The plurality of third line connection patterns LCP3 can be electrically connected to the plurality of second line connection patterns LCP2. For example, the third line connection pattern LCP3 can be electrically connected to the second line connection pattern LCP2 through a contact hole of the first insulating layer 2215a.

A second insulating layer 2215b can be disposed on a plurality of third line connection patterns LCP3. The second insulating layer 2215b can be disposed in the display area DA, the first non-display area NDA1, and the second non-display area NDA2, and may not be disposed in the entirety or part of the bending area BA. For example, the second insulating layer 2215b can be removed from the entirety or part of the bending area BA. The second insulating layer 2215b can be composed of an organic insulating material. For example, the second insulating layer 2215b can be composed of a photo resist, a polyimide (PI), or a photo acryl-based material.

A plurality of fourth line connection patterns LCP4 can be arranged on the second insulating layer 2215b. The plurality of fourth line connection patterns LCP4 can be electrically connected to a plurality of third line connection patterns LCP3. For example, the fourth line connection patterns LCP4 can be electrically connected to the third line connection patterns LCP3 through a contact hole of the second insulating layer 2215b.

In the non-display area NDA, a plurality of pad connection patterns PCP can be arranged on the second protection layer 2213b. A plurality of pad connection patterns PCPs can be wiring for transmitting a signal transmitted from a flexible printed circuit 1602 to a pad section 1621 to a driver DRV of a display area DA. For example, a plurality of pad connection patterns PCP can be electrically connected to a plurality of pads PD and can receive signals from the flexible printed circuit 1602 through the plurality of pads PDs. The flexible printed circuit 1602 can be connected to a printed circuit board 1604(see FIG. 16).

For example, a plurality of pad connection patterns PCP can extend from the pad section 1621 toward the display area DA and transmit signals to the wiring of the display area DA. In this case, a plurality of pad connection patterns PCP can function as link line LL (see FIG. 20). The plurality of pad connection patterns PCP can include a first pad connection pattern PCP1, a second pad connection pattern PCP2, a third pad connection pattern PCP3, and a fourth pad connection pattern PCP4.

The plurality of first pad connection patterns PCP1 can be arranged on the second protection layer 2213b. Each of the plurality of first pad connection patterns PCP1 can be arranged across the second non-display area NDA2, the bending area BA, and the first non-display area NDA1. Each of the plurality of first pad connection patterns PCP1 can include a first portion arranged in the bending area BA, a second portion extending from the first portion to the first non-display area NDA1, and a third portion extending from the first portion to the second non-display area NDA2. Each of the plurality of first pad connection patterns PCP1 can extend from the first non-display area NDA1 to a portion of the display area DA. The plurality of first pad connection patterns PCP1 can transmit a signal transmitted from the flexible printed circuit 1602 to the pad portion 1621 to the driver DRV of the display area DA.

Each of the plurality of first pad connection patterns PCP1 can be electrically connected to the pad PD of the pad section 1621 through connection patterns arranged in the second non-display area NDA2. Here, the connection patterns electrically connecting each of the plurality of first pad connection patterns PCP1 to the pad PD can include at least one of the second pad connection pattern PCP2, the third pad connection pattern PCP3, and the fourth pad connection pattern PCP4 arranged in the second non-display area NDA2.

Each of the plurality of first pad connection patterns PCP1 can be electrically connected to the driver DRV through connection patterns arranged in the display area DA. Here, the connection patterns electrically connecting each of the plurality of first pad connection patterns PCP1 to the driver DRV can include at least one of the second pad connection pattern PCP2, the third pad connection pattern PCP3, and the fourth pad connection pattern PCP4 arranged in the display area DA.

The plurality of second pad connection patterns PCP2 can be arranged on the third protection layer 2214. The plurality of second pad connection patterns PCP2 can be arranged in the second non-display area NDA2. The second pad connection pattern PCP2 can be electrically connected to the first pad connection pattern PCP1 through a contact hole of the third protection layer 2214. Therefore, the signal supplied from the flexible printed circuit 1602 can be transmitted to the first pad connection pattern PCP1 through the second pad connection pattern PCP.

The third pad connection pattern PCP3 can be arranged on the first insulating layer 2215a. The third pad connection pattern PCP3 can be arranged in the second non-display area NDA2. The third pad connection pattern PCP3 can be electrically connected to the second pad connection pattern PCP2 through a contact hole of the first insulating layer 2215a. Therefore, the signal supplied from the flexible printed circuit 1602 can be transmitted to the second pad connection pattern PCP2 through the third pad connection pattern PCP3, and the signal transmitted to the second pad connection pattern PCP2 can be transmitted again to the first pad connection pattern PCP1.

The fourth pad connection pattern PCP4 can be arranged on the second insulating layer 2215b. The fourth pad connection pattern PCP4 can be arranged in the second non-display area NDA2. The fourth pad connection pattern PCP4 can be electrically connected to the third pad connection pattern PCP3 through a contact hole of the second insulating layer 2215b. The pad PD of the pad section 1621 can be electrically connected to the fourth pad connection pattern PCP4 through a contact hole of the third insulating layer 2215c.

A signal supplied from a flexible printed circuit 1602 is input to a pad PD of a pad section 1621, and a signal input to the pad PD is transmitted to a third pad connection pattern PCP3 through a fourth pad connection pattern PCP4, and a signal transmitted to the third pad connection pattern PCP3 can be transmitted again to a first pad connection pattern PCP1 through a second pad connection pattern PCP2. A signal transmitted to the first pad connection pattern PCP1 can be transmitted to a driver DRV through connection patterns arranged in a display area DA.

A plurality of line connection patterns LCP and a plurality of pad connection patterns PCP can be arranged in various metal layers. The plurality of line connection patterns LCP and the plurality of pad connection patterns PCP can be formed of any one of a conductive material having excellent ductility and various conductive materials used in a display area DA.

For example, a metal pattern such as a first pad connection pattern PCP1 at least partially disposed in the bending area BA can be composed of a conductive material having excellent ductility, such as gold (Au), silver (Ag), or aluminum (Al). For another example, the plurality of line connection patterns LCP and the plurality of pad connection patterns PCP can be composed of molybdenum (Mo), chromium (Cr), titanium (Ti), nickel (Ni), neodymium (Nd), copper (Cu), and an alloy of silver (Ag) and magnesium (Mg), or an alloy thereof.

A third insulating layer 2215c can be disposed on the plurality of line connection patterns LCP and the plurality of pad connection patterns PCP. The third insulating layer 2215c is disposed in the display area DA, the first non-display area NDA1, and the second non-display area NDA2, and can be disposed in all or part of the bending area BA. In the bending area BA, a part of the third insulating layer 2215c can be removed. The third insulating layer 2215c can be composed of an organic insulating material. For example, the third insulating layer 2215c can be composed of a photo resist, a polyimide (PI), or a photo acryl-based material.

A plurality of banks BNK can be disposed on the third insulating layer 2215c in the display area DA. The plurality of banks BNKs can be arranged to overlap with at least a portion of each of the plurality of sub-pixels SPa, SPb and SPc. For example, the first sub-pixel SPa can include a first light emitting device EDa that emits a first color light, the second sub-pixel SPb can include a second light emitting device EDb that emits a second color light, and the third sub-pixel SPc can include a third light emitting device EDc that emits a third color light.

The light emitting device ED can be located on the bank BNK. As an example, one light emitting device ED can be arranged on top of each of the plurality of banks BNKs. As another example, two or more light emitting devices ED can be arranged on top of each of the plurality of banks BNK. The two or more light emitting devices EDs arranged on top of each of the plurality of banks BNK can be light emitting devices of the same type. For example, the light emitting devices of the same type can be light emitting devices that emit the same color light. For example, the two or more light emitting devices ED arranged on top of each of the plurality of banks BNK can include a main light emitting device and a redundancy light emitting device.

In the display area DA, a plurality of row connection electrodes RCE can be arranged on the third insulating layer 2215c. The plurality of row connection electrodes RCE can transfer a low-potential voltage VSS output from the driver DRV to the row line RL.

In the display area DA, a plurality of column lines CL can be arranged on the third insulating layer 2215c. The plurality of column lines CL can be arranged in an area between the plurality of banks BNK. For example, the plurality of column lines CL can be arranged adjacent to one of the plurality of banks BNK.

Each of the plurality of column lines CL can include a wiring portion and a column connection electrode CCE protruding from the wiring portion. The wiring portion and the column connection electrode CCE included in each of the plurality of column lines CL can be formed integrally or can be different metals that are electrically connected.

For example, each of the plurality of column lines CL can include a column connection electrode CCE that is a portion protruding above an adjacent bank BNK among the plurality of banks BNK. The column connection electrode CCE can be disposed on the bank BNK and electrically connected to the first electrode of the light emitting device ED. The column connection electrode CCE of each of the plurality of column lines CL can be arranged to extend along the side and upper surface of the bank BNK. The column connection electrode CCE can be an electrode electrically connected to each of the plurality of column lines CL or can be a portion protruding from each of the plurality of column lines CL. For example, the column line CL and the column connection electrode CCE can be connected along the side of the bank BNK.

Referring to FIG. 23, the column connection electrode CCE of the column line CL can be composed of one conductive layer or multiple conductive layers. For example, a column connection electrode CCE electrically connected to a column line CL or protruding from the column line CL can include a first conductive layer 2301, a second conductive layer 2302, a third conductive layer 2303, and a fourth conductive layer 2304.

The first conductive layer 2301 can be disposed on a bank BNK. The second conductive layer 2302 can be disposed on the first conductive layer 2301. The third conductive layer 2303 can be disposed on the second conductive layer 2302, and the fourth conductive layer 2304 can be disposed on the third conductive layer 2303. For example, each of the first conductive layer 2301, the second conductive layer 2302, the third conductive layer 2303, and the fourth conductive layer 2304 can be composed of titanium (Ti), molybdenum (Mo), aluminum (Al), or titanium (Ti) and indium tin oxide (ITO).

Among the plurality of conductive layers constituting the column connection electrode CCE, some conductive layers having good reflection efficiency can be configured as an alignment key and/or a reflector for aligning the light emitting devices ED. For example, among the plurality of conductive layers constituting the column connection electrode CCE, the second conductive layer 2302 can include a reflective material. For example, the second conductive layer 2302 can include aluminum (Al). Accordingly, the second conductive layer 2302 can be configured as a reflector. In addition, due to the high reflection efficiency of the second conductive layer 2302, it can be easily identified in the manufacturing process, and thus the position or transfer position of the light emitting device ED can be aligned based on the second conductive layer 2302.

For example, in order to configure the second conductive layer 2302 as a reflector, the third conductive layer 2303 and the fourth conductive layer 2304 disposed on the second conductive layer 2302 can be partially removed or etched. For example, a portion of the third conductive layer 2303 and the fourth conductive layer 2304 disposed on the bank BNK can be removed or etched to expose the upper surface of the second conductive layer 2302. For example, the openings of the third conductive layer 2303 and the fourth conductive layer 2304 can overlap with a portion of the upper surface of the second conductive layer 2302. For example, in the third conductive layer 2303 and the fourth conductive layer 2304, the central portion and the edge portion where an electrode connection pattern ECP is arranged can remain, and the remaining portions excluding this portion (e.g., the central portion, the edge portion) can be removed. For example, the edge portion of each of the third conductive layer 2303 made of titanium (Ti) and the fourth conductive layer 2304 made of indium tin oxide (ITO) may not be etched. Accordingly, it is possible to prevent other conductive layers of the column connection electrode CCE of the column line CL from being corroded by the TMAH (Tetra Methyl Ammonium Hydroxide) solution used in the mask process of the column connection electrode CCE.

The first conductive layer 2301 and the third conductive layer 2303 can include titanium (Ti) or molybdenum (Mo). The second conductive layer 2302 can include aluminum (Al). The fourth conductive layer 2304 can include a transparent conductive oxide layer such as indium tin oxide (ITO) or indium zinc oxide (IZO) that has good adhesion to the electrode connection pattern ECP and corrosion resistance and acid resistance.

The first conductive layer 2301, the second conductive layer 2302, the third conductive layer 2303, and the fourth conductive layer 2304 can be sequentially deposited and then patterned by performing a photolithography process and an etching process.

Two or more of the column connection electrode CCE, the column line CL, the row connection electrode RCE, and the pad PD can be arranged on the same layer. The column connection electrode CCE, the column line CL, the row connection electrode RCE, and the pad PD can be composed of a single layer or multiple layers of a conductive material. For example, two or more of the column connection electrode CCE, the column line CL, the row connection electrode RCE, and the pad PD can be composed of a multiple layer of indium tin oxide (ITO)/titanium (Ti)/aluminum (Al)/titanium (Ti).

An electrode connection pattern ECP can be disposed between a first electrode E1 and the column connection electrode CCE in each of a plurality of sub-pixels. The electrode connection pattern ECP can bond the light emitting device ED to the column connection electrode CCE. The column connection electrode CCE and the light emitting device ED can be electrically connected through eutectic bonding using the electrode connection pattern ECP. For example, if the electrode connection pattern ECP is composed of indium (In) and an auxiliary electrode 130 of the light emitting device ED is composed of gold (Au), the electrode connection pattern ECP and the auxiliary electrode 130 of the light emitting device ED can be bonded by applying heat and pressure in a transfer process of the light emitting device ED. Through eutectic bonding, the light emitting device ED can be bonded to the electrode connection pattern ECP and the column connection electrode CCE without a separate adhesive. For example, the electrode connection pattern ECP can be composed of indium (In), tin (Sn), or an alloy thereof. For example, the electrode connection pattern ECP can be a bonding pad.

The passivation layer 2216 can be disposed on a plurality of column lines CL, a plurality of column connection electrodes CCE, a plurality of row connection electrodes RCE, and a third insulating layer 2215c.

For example, the passivation layer 2216 can be disposed on a display area DA, a first non-display area NDA1, and a second non-display area NDA2. In the entirety or a portion of the bending area BA, at least a portion of the passivation layer 2216 covering the plurality of pads PD can be removed. A portion of the passivation layer 2216 covering the plurality of pads PD in the second non-display area NDA2 can be removed. In addition, as illustrated in FIG. 23, the passivation layer 2216 can be removed from the area where the electrode connection pattern ECP is arranged.

Since the passivation layer 2216 is arranged to cover the remaining area except for the bending area BA, the plurality of pads PD, and the area where the electrode connection pattern ECP is arranged, the penetration of moisture or impurities into the light emitting device ED can be reduced. For example, the passivation layer 2216 can be composed of a single layer or multiple layers of silicon oxide (SiOx) or silicon nitride (SiNx). For example, the passivation layer 2216 can be a protection layer or an insulating layer. For example, as illustrated in FIG. 23, the passivation layer 2216 can include a hole through which the electrode connection pattern ECP is exposed. For example, the hole of the passivation layer 2216 can overlap with the electrode connection pattern ECP.

The light emitting device ED can be arranged on the electrode connection pattern ECP in each of a plurality of sub-pixels SP. The light emitting device ED can be formed on a silicon wafer by a method such as Metal Organic Chemical Vapor Deposition (MOCVD), Chemical Vapor Deposition (CVD), Plasma-Enhanced Chemical Vapor Deposition (PDCVD), Molecular Beam Epitaxy (MBE), Hydride Vapor Phase Epitaxy (HVPD), or Sputtering.

The light emitting device ED can include a first electrode E1, a first semiconductor layer 111, an emission layer 112, a second semiconductor layer 113, a second electrode E2, an encapsulation layer 121 and 122, and an auxiliary electrode 130. In some cases, the light emitting device ED may not include the encapsulation layer 121 and 122, and the auxiliary electrode 130, and a description overlapping with the configuration of FIG. 1 can be omitted.

The auxiliary electrode 130 of the light emitting device ED can be disposed between the first electrode E1 and the electrode connection pattern ECP. For example, the auxiliary electrode 130 of the light emitting device ED can electrically connect the first electrode E1 and the column connection electrode CCE. The column line voltage (e.g., anode voltage) output from the driver DRV can be applied to the first semiconductor layer 111 through the column line CL, the column connection electrode CCE, the auxiliary electrode 130, and the first electrode E1.

The second electrode E2 of the light emitting device ED can be disposed on the second semiconductor layer 113. For example, the second electrode E2 of the light emitting device ED can electrically connect the second semiconductor layer 113 and the row line RL. The row line voltage (e.g., referred to as the low potential voltage VSS as the cathode voltage) output from the driver DRV can be applied to the second semiconductor layer 113 through the row connection electrode RCE, the row line RL, and the second electrode E2. The second electrode E2 of the light emitting device ED can be composed of a transparent conductive material so that light emitted from the light emitting device ED can be directed toward the upper portion of the light emitting device ED.

The light emitting device ED can have a vertical structure. Alternatively, the light emitting device ED can have a lateral structure or a flip chip structure.

The structure of the light emitting device ED illustrated in FIG. 23 can be substantially equally applied to all of the first light emitting device EDa, the second light emitting device EDb, and the third light emitting device EDc.

A first optical layer 2217a can be arranged to surround a plurality of light emitting devices ED in the display area DA. For example, the first optical layer 2217a can be disposed to surround a side of the light emitting device ED. For example, the first optical layer 2217a can be arranged to cover a plurality of light emitting devices ED and the bank BNK in the area of a plurality of sub-pixels SP. For example, the first optical layer 2217a can cover a bank BNK, a portion of the passivation layer 2216, and a region between the plurality of light emitting devices ED. The first optical layer 2217a can be arranged or covered between a plurality of light emitting devices ED included in one pixel and between a plurality of banks BNK. For example, the first optical layer 2217a can be arranged to surround the side of the light emitting devices ED and the banks BNK between the passivation layer 2216 and the row line RL. For example, the first optical layer 2217a can be a diffusion layer or a sidewall diffusion layer.

The first optical layer 2217a can include a plurality of light-scattering particles. The first optical layer 2217a can include an organic insulating material in which fine particles (i.e., light-scattering particles) are dispersed. For example, the first optical layer 2217a can be composed of siloxane in which fine metal particles, such as titanium dioxide (TiO2) particles, are dispersed. Light from the plurality of light emitting device ED can be scattered by the fine particles included in the first optical layer 2217a and emitted to the outside of the display device 1600. Accordingly, the first optical layer 2217a can improve the extraction efficiency of light emitted from the plurality of light emitting devices ED.

The first optical layer 2217a can be arranged on each of a plurality of pixels, or can be arranged together on some pixels arranged in the same row. For example, the first optical layer 2217a can be arranged on each of a plurality of pixels, or the plurality of pixels can share one first optical layer 2217a. For another example, each of the plurality of sub-pixels can separately include a first optical layer 2217a.

In the display area DA, a second optical layer 2217b can be arranged on the passivation layer 2216. For example, the second optical layer 2217b can be arranged to surround the first optical layer 2217a. For example, the second optical layer 2217b can be arranged in an area between the plurality of pixels. For example, the second optical layer 2217b can be a diffusion layer, a diffusion layer window, or a window diffusion layer.

The second optical layer 2217b can be composed of an organic insulating material. The second optical layer 2217b can be composed of the same material as the first optical layer 2217a. For example, the first optical layer 2217a can include fine particles, and the second optical layer 2217b may not include fine particles. For example, the second optical layer 2217b can be composed of siloxane.

For example, the thickness of the first optical layer 2217a can be smaller than the thickness of the second optical layer 2217b. Accordingly, when viewed from a planar view, the area where the first optical layer 2217a is disposed can include a concave portion that is sunken inwardly from the upper surface of the second optical layer 2217b.

The row line RL can be disposed on the first optical layer 2217a and the second optical layer 2217b. The second optical layer 2217b can include at least one contact hole. For example, the row line RL can be electrically connected to a plurality of row connection electrodes RCE through contact holes of the second optical layer 2217b. For example, the row line RL can be disposed on a plurality of light emitting devices ED. For example, the row line RL can include a transparent conductive oxide such as indium tin oxide (ITO) or indium zinc oxide (IZO). The row line RL can be disposed on the second electrode E2 of the light emitting device ED. For example, the row line RL can be arranged to be in contact with the second electrode E2 of the light emitting device ED. For example, the row line RL can overlap with the first optical layer 2217a. For example, the row line RL can cover a plane on the outside of the first optical layer 2217a.

The row line RL can extend continuously in the first direction X of the substrate 1521. Accordingly, the row line RL can be commonly connected to a plurality of pixels arranged in the first direction X of the substrate 1521. For example, the row line RL can be commonly connected to a plurality of pixels.

The row line RL can be continuously extended on the first optical layer 2217a, the second optical layer 2217b, and the light emitting device ED. The area where the first optical layer 2217a is disposed can include a concave portion that is sunken inwardly from the upper surface of the second optical layer 2217b. Accordingly, the first part of the row line RL disposed on the first optical layer 2217a can be disposed along the concave portion, and thus can be disposed at a lower position than the second part of the row line RL disposed on the second optical layer 2217b.

A third optical layer 2217c can be disposed on the row line RL. The third optical layer 2217c can be disposed so as to overlap with a plurality of light emitting devices ED and the first optical layer 2217a. Since the third optical layer 2217c is arranged on the row line RL and the plurality of light emitting devices ED, it is possible to improve a mura that can occur in some of the plurality of light emitting devices ED. For example, when transferring a plurality of light emitting devices ED onto the substrate 1521 of the display panel 1520, there can occur an area where the spacing between the plurality of light emitting devices ED is not uniform due to process deviation. If the spacing between the plurality of light emitting devices ED is not uniform, an emission areas of each of the plurality of light emitting devices ED can be arranged unevenly, and thus a mura can be visible to the user. Accordingly, since the third optical layer 2217c is arranged to uniformly diffuse light over the plurality of light emitting devices ED, it is possible to reduce light emitted from some of the light emitting devices ED from being visible as a mura. Accordingly, since the light emitted from the plurality of light emitting devices EDs is evenly diffused by the third optical layer 2217c and extracted to the outside of the display device 1600, the luminance uniformity of the display device 1600 can be improved.

The third optical layer 2217c can be composed of an organic insulating material in which fine particles are dispersed. For example, the third optical layer 2217c can be composed of siloxane in which fine metal particles such as titanium dioxide (TiO2) particles are dispersed, but the embodiments of the present disclosure are not limited thereto. For example, the third optical layer 2217c can be composed of the same material as the first optical layer 2217a. For example, the third optical layer 2217c can be a diffusion layer or an upper diffusion layer.

Light from a plurality of light emitting devices ED can be scattered by fine particles dispersed in a third optical layer 2217c and emitted to the outside of the display device 1600. The third optical layer 2217c can evenly mix light emitted from a plurality of light emitting devices ED, thereby further improving the luminance uniformity of the display device 1600. For example, light emitted from a plurality of light emitting device ED covered by a black matrix BM disposed on a third optical layer 2217c can be scattered by the third optical layer 2217c and directed toward the outside of the display device 1600. In addition, the light extraction efficiency of the display device 1600 can be improved by the light scattered from the plurality of fine particles, thereby enabling the display device 1600 to be driven at low power.

A black matrix BM can be arranged on the row line RL, the first optical layer 2217a, the second optical layer 2217b, and the third optical layer 2217c in the display area DA. For example, the black matrix BM can fill a contact hole of the second optical layer 2217b. The black matrix BM can be configured to cover the display area DA, so that the color mixing of light and external light reflection of the plurality of sub-pixels can be reduced. For example, the black matrix BM can also be arranged in the contact hole where the row line RL and the row connection electrode RCE are connected, so that light leakage between the neighboring plurality of sub-pixels can be prevented. For example, the black matrix BM can be composed of an opaque material. For example, the black matrix BM can be an organic insulating material to which a black pigment or a black dye is added.

A cover layer 2218 can be arranged on the black matrix BM in the display area DA. The cover layer 2218 can be disposed on the third optical layer 2217c. The cover layer 2218 can protect a configuration under the cover layer 2218. For example, the cover layer 2218 can be composed of an organic insulating material. For example, the cover layer 2218 can be composed of a photo resist, polyimide (PI), or photo acryl-based material. For example, the cover layer 2218 can be an overcoating layer or an insulating layer.

In the display panel 1520 according to embodiments of the present disclosure, a refractive index of the third optical layer 2217c can be greater than a refractive index of the second electrode E2 and less than a refractive index of the cover layer 2218. Since the refractive index of the third optical layer 2217c has a value between the refractive index of the second electrode E2 and the refractive index of the cover layer 2218, it is possible to improve the extraction efficiency of light emitted from the plurality of light emitting device ED.

A polarizing layer 224 can be arranged on the cover layer 2218 via a first adhesive layer 222. A cover member 2150 can be arranged on the polarizing layer 224 via a second adhesive layer 226. For example, the first adhesive layer 222 and the second adhesive layer 226 can include an optically clear adhesive (OCA), an optically clear resin (OCR), or a pressure sensitive adhesive (PSA).

A plurality of pads PD can be arranged on a third insulating layer 2215c in a second non-display area NDA2. For example, at least a portion of the plurality of pads PD can be exposed from a passivation layer 2216. For example, the plurality of pads PD can be electrically connected to a fourth pad connection pattern PCP4 through a contact hole of the third insulating layer 2215c.

An adhesive layer ACF can be arranged on the plurality of pads PD. The adhesive layer ACF can be an adhesive layer in which conductive balls are dispersed in an insulating material. The adhesive layer ACF can be disposed between a plurality of pads PD and a flexible printed circuit 1602, so that the flexible printed circuit 1602 can be attached or bonded to the plurality of pads PD. For example, the adhesive layer ACF can be an anisotropic conductive film ACF.

A flexible printed circuit 1602 can be disposed on the adhesive layer ACF. The flexible printed circuit 1602 can be electrically connected to the plurality of pads PD through the adhesive layer ACF. Accordingly, a signal supplied from the flexible printed circuit 1602 can be transmitted to a driver DRV of a display area DA through the plurality of pads PD, the fourth pad connection pattern PCP4, the third pad connection pattern PCP3, the second pad connection pattern PCP2, and the first pad connection pattern PCP1.

The display panel 1520 according to the embodiments of the present disclosure can include a substrate 1521, a layer stack 2110 on a plurality of drivers DRV disposed on the substrate 1521, an optical layer 2217a disposed between a plurality of light emitting devices EDa, EDb and EDc on the layer stack 2110, an adhesive layer 226 disposed on the plurality of light emitting devices EDa, EDb and EDc and the optical layer 2217a, and a cover member 2150 disposed on the adhesive layer 226.

The plurality of column lines CL can be disposed between the layer stack 2110 and the plurality of light emitting devices EDa, EDb and EDc. The plurality of row lines RL can be arranged on a plurality of light emitting devices EDa, EDb and EDc and an optical layer 2217a. The plurality of row lines RL can be arranged between a plurality of light emitting devices EDa, EDb and EDc, an optical layer 2217a, and an adhesive layer 226.

The layer stack 2110 can include a plurality of protection layers 2213a, 2213b and 2214 arranged on the side and upper surface of each of a plurality of drivers DRV, a plurality of insulating layers 2215a, 2215b and 2215c arranged on the plurality of protection layers 2213a, 2213b and 2214, and a bank BNK arranged on the plurality of insulating layers.

The plurality of protection layers 2213a, 2213b and 2214 can further include a side protection layer 2213 disposed on each side of the plurality of drivers DRV and an upper protection layer 2214 disposed on the upper surface of each of the plurality of drivers DR.

The side protection layer 2213 can include a first protection layer 2213a disposed on the substrate 1521 and a second protection layer 2213b disposed on the first protection layer 2213a. The upper protection layer 2214 can include a third protection layer 2214 disposed on the second protection layer 2213b and the plurality of drivers DRV.

The plurality of insulating layers 2215a, 2215b and 2215c can include a first insulating layer 2215a disposed on the upper protection layer 2214, and a second insulating layer 2215b disposed on the first insulating layer 2215a. The plurality of insulating layers 2215a, 2215b and 2215c can further include a third insulating layer 2215c disposed on the second insulating layer 2215b.

Each of the plurality of light emitting devices EDa, EDb and EDc can be disposed on the bank BNK and positioned in an opening of the optical layer 2217a.

At least a portion of each of the plurality of column lines CL can extend onto the bank BNK on the plurality of insulating layers 2215a, 2215b and 2215c. Each of the plurality of row lines RL can be arranged on the optical layer 2217a and the plurality of light emitting devices EDa, EDb and EDc.

A first electrode E1 of each of the plurality of light emitting devices EDa, EDb and EDc can be electrically connected to at least a portion of a column line CL extending onto the bank BNK among the plurality of column lines CL. A second electrode E2 of each of the plurality of light emitting devices EDa, EDb and EDc can be electrically connected to one of the plurality of row lines RL.

The display panel 1520 according to the embodiments of the present disclosure can include a plurality of line connection patterns LCPs that connect each of a plurality of lines including a plurality of row lines RL and a plurality of column lines CL to a plurality of drivers DRV.

The plurality of line connection patterns LCPs can include a first line connection pattern LCP1 disposed on a side protection layer 2213, a second line connection pattern LCP2 disposed on an upper protection layer 2214 and electrically connected to the first line connection pattern LCP1 through a hole in the upper protection layer 2214, a third line connection pattern LCP3 disposed on a first insulating layer 2215a and electrically connected to the second line connection pattern LCP2 through a hole in the first insulating layer 2215a, and a fourth line connection pattern LCP4 disposed on a second insulating layer 2215b and electrically connected to the third line connection pattern LCP3 through a hole in the second insulating layer 2215b.

The first line connection pattern LCP1 can be electrically connected to one of the plurality of drivers DRV. The fourth line connection pattern LCP4 can be electrically connected to at least one second electrode E2 of the plurality of light emitting devices EDa, EDb and EDc, or can be electrically connected to at least one first electrode E1 of the plurality of light emitting devices EDa, EDb and EDc.

The side protection layer 2213 arranged on each side of the plurality of drivers DRV can include two or more organic layers.

The first and second protection layers 2213a and 2213b as the side protection layer 2213, the third protection layer 2214 as the upper protection layer 2214, and the first to third insulating layers 2215a, 2215b and 2215c can each be composed of organic layers.

A display device according to embodiments of the present disclosure can be described as follows.

A display device according to embodiments of the present disclosure can include a substrate, and a light emitting device disposed on the substrate and located in a display area. The light emitting device can include a first electrode, an intermediate layer disposed on the first electrode, a second electrode disposed on the intermediate layer, and an encapsulation layer surrounding at least a portion of the first electrode and the intermediate layer, wherein the second electrode is disposed on the intermediate layer and the encapsulation layer.

In the display device according to embodiments of the present disclosure, a back surface of the second electrode can be in contact with an upper surface of the encapsulation layer.

In the display device according to embodiments of the present disclosure, the encapsulation layer can include a side portion surrounding a side of the first electrode and the intermediate layer, and a lower portion surrounding a back surface of the first electrode and having at least one hole.

The display device according to embodiments of the present disclosure can further include an auxiliary electrode positioned below the lower portion, and electrically connected to the first electrode through the at least one hole.

In the display device according to embodiments of the present disclosure, each of the first electrode and the second electrode can be a transparent electrode, and the auxiliary electrode can be an opaque electrode.

In the display device according to embodiments of the present disclosure, the encapsulation layer can include a first encapsulation layer surrounding the first electrode and the intermediate layer, and a second encapsulation layer surrounding the first encapsulation layer.

In the display device according to embodiments of the present disclosure, the first encapsulation layer can include a material different from a material of the second encapsulation layer.

In the display device according to embodiments of the present disclosure, a thickness of the first encapsulation layer can be smaller than a thickness of the second encapsulation layer, or a density of the first encapsulation layer can be higher than a density of the second encapsulation layer.

In the display device according to embodiments of the present disclosure, the intermediate layer can include an emission layer, a first semiconductor layer between the first electrode and the emission layer, and a second semiconductor layer between the second electrode and the emission layer. The emission layer can be positioned closer to the first electrode than to the second electrode, and the encapsulation layer can cover a side of the emission layer.

The display device according to embodiments of the present disclosure can further include a first optical layer disposed to surround a side of the light emitting device and including a plurality of light-scattering particles, and a second optical layer disposed to surround the first optical layer and including at least one contact hole.

The display device according to embodiments of the present disclosure can further include a black matrix disposed on the first optical layer and the second optical layer. The black matrix can fill the contact hole of the second optical layer.

The display device according to embodiments of the present disclosure can further include a row line arranged on the second electrode, a third optical layer disposed on the row line, and a cover layer disposed on the third optical layer. A refractive index of the third optical layer can be greater than a refractive index of the second electrode and less than a refractive index of the cover layer.

The display device according to embodiments of the present disclosure can further include a driver disposed between the substrate and the light emitting device, and electrically connected to the first electrode and the second electrode.

The display device according to embodiments of the present disclosure can further include a side protection layer disposed on a side of the driver, an upper protection layer disposed on the side protection layer, an insulating layer disposed on the upper protection layer, and a bank disposed on the insulating layer. The light emitting device can be located on the bank.

The display device according to embodiments of the present disclosure can further include a column connection electrode disposed on the bank and electrically connected to the first electrode, and a column line disposed on the insulating layer. The column line and the column connection electrodes can be connected along a side of the bank.

The display device according to embodiments of the present disclosure can further include an electrode connection pattern disposed between the first electrode and the column connection electrode.

A method of manufacturing a light emitting device according to embodiments of the present disclosure can include forming a crystal layer on a sapphire substrate, forming a first metal layer on the crystal layer, separating the first metal layer into a plurality of first electrodes and etching the crystal layer to a predefined first depth, forming an encapsulation layer on a side of the crystal layer and on the plurality of first electrodes, forming at least one hole in the encapsulation layer, forming a plurality of auxiliary electrodes on the encapsulation layer and connecting the plurality of auxiliary electrodes to the plurality of first electrodes to form a first intermediate product, bonding the first intermediate product to a first carrier substrate using a first adhesive layer, and positioning the plurality of auxiliary electrodes on the first carrier substrate, removing the first adhesive layer and an upper portion of the encapsulation layer, forming a second metal layer on the first adhesive layer and the encapsulation layer, forming a second adhesive layer on the second metal layer and forming a second carrier substrate on the second adhesive layer, removing the first carrier substrate and the first adhesive layer to form a second intermediate product, and separating the second metal layer into a plurality of second electrodes to form a plurality of light emitting devices from the second intermediate product, wherein the second electrodes are disposed on the encapsulation layer.

The method of manufacturing a light emitting device according to embodiments of the present disclosure can further include, between the step of forming the second intermediate product and the step of forming the plurality of light emitting devices, a step of supplying a first voltage to all or part of the plurality of auxiliary electrodes and supplying a second voltage different from the first voltage to the second metal layer in a state of the second intermediate product.

In the method of manufacturing a light emitting device according to embodiments of the present disclosure, in the step of etching the crystal layer, two adjacent first electrodes among the plurality of first electrodes can be spaced apart by a predefined distance, and the second intermediate product can be in a state where the second metal layer is exposed in the step of forming the second intermediate product.

In the method of manufacturing a light emitting device according to embodiments of the present disclosure, the second metal layer can include a transparent electrode material.

In the method of manufacturing a light emitting device according to embodiments of the present disclosure, each of the plurality of light emitting devices can include a corresponding first electrode among the plurality of first electrodes, a corresponding second electrode among the plurality of second electrodes, and an intermediate layer between the corresponding first electrode and the corresponding second electrode. The first depth can correspond to a thickness of the intermediate layer.

The above description has been presented to enable any person skilled in the art to make and use the technical idea of the present invention, and has been provided in the context of a particular application and its requirements. Various modifications, additions and substitutions to the described embodiments will be readily apparent to those skilled in the art, and the general principles defined herein can be applied to other embodiments and applications without departing from the spirit and scope of the present invention. The above description and the accompanying drawings provide an example of the technical idea of the present invention for illustrative purposes only. For example, the disclosed embodiments are intended to illustrate the scope of the technical idea of the present invention.

What is claimed is:

1. A display device comprising:
a substrate; and
a light emitting device disposed on the substrate and located in a display area,
wherein the light emitting device includes:
a first electrode;
an intermediate layer disposed on the first electrode;
a second electrode disposed on the intermediate layer; and
an encapsulation layer surrounding at least a portion of the first electrode and the intermediate layer,
wherein the second electrode is disposed on the intermediate layer and the encapsulation layer.

2. The display device of claim 1, wherein a back surface of the second electrode is in contact with an upper surface of the encapsulation layer.

3. The display device of claim 1, wherein the encapsulation layer includes:
a side portion surrounding a side of the first electrode and the intermediate layer; and
a lower portion surrounding a back surface of the first electrode and having at least one hole,
wherein the display device further comprises an auxiliary electrode positioned below the lower portion of the encapsulation layer, and electrically connected to the first electrode through the at least one hole.

4. The display device of claim 3, wherein each of the first electrode and the second electrode is a transparent electrode, and
wherein the auxiliary electrode is an opaque electrode.

5. The display device of claim 1, wherein the encapsulation layer includes:
a first encapsulation layer surrounding the first electrode and the intermediate layer; and
a second encapsulation layer surrounding the first encapsulation layer.

6. The display device of claim 5, wherein the first encapsulation layer includes a material different from a material of the second encapsulation layer.

7. The display device of claim 5, wherein a thickness of the first encapsulation layer is smaller than a thickness of the second encapsulation layer, or a density of the first encapsulation layer is higher than a density of the second encapsulation layer.

8. The display device of claim 1, wherein the intermediate layer includes:
an emission layer;
a first semiconductor layer between the first electrode and the emission layer; and
a second semiconductor layer between the second electrode and the emission layer,
wherein the emission layer is positioned closer to the first electrode than to the second electrode, and
wherein the encapsulation layer covers a side of the emission layer.

9. The display device of claim 1, further comprising:
a first optical layer disposed to surround a side of the light emitting device and including a plurality of light-scattering particles; and
a second optical layer disposed to surround the first optical layer and including at least one contact hole.

10. The display device of claim 9, further comprising a black matrix disposed on the first optical layer and the second optical layer,
wherein the black matrix fills the at least one contact hole of the second optical layer.

11. The display device of claim 1, further comprising:
a row line arranged on the second electrode;
a third optical layer disposed on the row line; and
a cover layer disposed on the third optical layer,
wherein a refractive index of the third optical layer is greater than a refractive index of the second electrode and is less than a refractive index of the cover layer.

12. The display device of claim 1, further comprising a driver disposed between the substrate and the light emitting device, and electrically connected to the first electrode and the second electrode.

13. The display device of claim 12, further comprising:
a side protection layer disposed on a side of the driver;
an upper protection layer disposed on the side protection layer;
an insulating layer disposed on the upper protection layer; and
a bank disposed on the insulating layer,
wherein the light emitting device is located on the bank.

14. The display device of claim 13, further comprising:
a column connection electrode disposed on the bank and electrically connected to the first electrode; and
a column line disposed on the insulating layer,
wherein the column line and the column connection electrodes are connected along a side of the bank.

15. The display device of claim 14, further comprising an electrode connection pattern disposed between the first electrode and the column connection electrode.

16. A method of manufacturing a light emitting device, the method comprising:
forming a crystal layer on a sapphire substrate;
forming a first metal layer on the crystal layer;
separating the first metal layer into a plurality of first electrodes and etching the crystal layer to a predefined first depth;
forming an encapsulation layer on a side of the crystal layer and on the plurality of first electrodes;
forming at least one hole in the encapsulation layer;
forming a plurality of auxiliary electrodes on the encapsulation layer and connecting the plurality of auxiliary electrodes to the plurality of first electrodes to form a first intermediate product;
bonding the first intermediate product to a first carrier substrate using a first adhesive layer, and positioning the plurality of auxiliary electrodes on the first carrier substrate;
removing the first adhesive layer and an upper portion of the encapsulation layer;
forming a second metal layer on the first adhesive layer and the encapsulation layer;
forming a second adhesive layer on the second metal layer and forming a second carrier substrate on the second adhesive layer;
removing the first carrier substrate and the first adhesive layer to form a second intermediate product; and
separating the second metal layer into a plurality of second electrodes to form a plurality of light emitting devices from the second intermediate product,
wherein the plurality of second electrodes are disposed on the encapsulation layer.

17. The method of claim 16, further comprising:
between the forming the second intermediate product and the forming the plurality of light emitting devices, supplying a first voltage to all or part of the plurality of auxiliary electrodes and supplying a second voltage different from the first voltage to the second metal layer in a state of the second intermediate product.

18. The method of claim 16, wherein, in the etching the crystal layer, two adjacent first electrodes among the plurality of first electrodes are spaced apart by a predefined distance, and the second intermediate product is in a state where the second metal layer is exposed in the forming the second intermediate product.

19. The method of claim 16, wherein the second metal layer includes a transparent electrode material.

20. The method of claim 16, wherein each of the plurality of light emitting devices includes:
a corresponding first electrode among the plurality of first electrodes;
a corresponding second electrode among the plurality of second electrodes; and
an intermediate layer between the corresponding first electrode and the corresponding second electrode,
wherein the predefined first depth corresponds to a thickness of the intermediate layer.
